(19) United States
(12) Patent Application Publication
(10) Pub. No.: US 2022/0033999 A1
(43) Pub. Date: Feb. 3, 2022

(54) High-Strength Refractory Fibrous Materials

(71) Applicant: Dynetics, Inc., Huntsville, AL (US)

(72) Inventors: James L. Maxwell, Scottsboro, AL (US); Nicholas Webb, Madison, AL (US); Ryan Hooper, Madison, AL (US); James Allen, Huntsville, AL (US)

(21) Appl. No.: 17/504,647

(22) Filed: Oct. 19, 2021

Related U.S. Application Data
(62) Division of application No. 14/931,564, filed on Nov. 3, 2015.
Application No. 14/931,564 is a continuation-in-part of application No. 14/827,752, filed on Aug. 17, 2015, now Pat. No. 10,167,555.
(60) Provisional application No. 62/038,705, filed on Aug. 18, 2014.
(60) Provisional application No. 62/074,703, filed on Nov. 4, 2014.
(60) Provisional application No. 62/074,739, filed on Nov. 4, 2014.

(51) Int. Cl. D01F 9/12; D01F 9/127; C04B 35/58; C04B 35/583; C04B 35/622; C23C 16/46; C04B 35/584; C23C 16/44; C23C 16/48; C23C 16/30

(52) U.S. Cl. CPC D01F 9/12; C04B 2235/781; D01F 9/1277; C04B 35/58007; C04B 35/583; C04B 35/62295; C23C 16/463; C04B 35/62286; C04B 35/58028; C04B 35/6229; C04B 35/584; C04B 35/58; C23C 16/4418; C23C 16/483; C23C 16/30; C04B 2235/76; C04B 2235/5296; D01F 9/1272

(57) ABSTRACT

The disclosed materials, methods, and apparatus, provide novel ultra-high temperature materials (UHTM) in fibrous forms/structures; such “fibrous materials” can take various forms, such as individual filaments, short-shaped fiber, tows, ropes, wools, textiles, lattices, nano/microstructures, mesostructured materials, and sponge-like materials. At least four important classes of UHTM materials are disclosed in this invention: (1) carbon, doped-carbon and carbon alloy materials, (2) materials within the boron-carbon-nitride-X system, (3) materials within the silicon-carbon-nitride-X system, and (4) highly-refractory materials within the tantalum-hafnium-carbon-nitride-X and tantalum-hafnium-carbon-boron-nitride-X system. All of these material classes offer compounds/mixtures that melt or sublime at temperatures above 1800° C.—and in some cases are among the highest melting point materials known (exceeding 3000° C.). In many embodiments, the synthesis/fabrication is from gaseous, solid, semi-solid, liquid, critical, and supercritical precursor mixtures using one or more low molar mass precursor(s), in combination with one or more high molar mass precursor(s). Methods for controlling the growth, composition, and structures of UHTM materials through control of the thermal diffusion region are disclosed.

### CROSS-REFERENCE TO RELATED APPLICATIONS

This application is a divisional of, and claims priority to, and the benefit of, U.S. application Ser. No. 14/931,564, titled “High-Strength Refractory Fibrous Materials” filed Nov. 3, 2015, which is a continuation-in-part of, and claims priority to, and the benefit of, U.S. application Ser. No. 14/827,752 titled “Method and Apparatus of Fabricating Fibers and Microstructures from Disparate Molar Mass Precursors,” filed Aug. 17, 2015, now U.S. Pat. No. 10,167,555, which claims priority to, and the benefit of, U.S. Application Ser. No. 62/038,705 titled “Method and Apparatus of Fabricating Fibers from Disparate Molecular Mass Gaseous, Liquid, Critical and Supercritical Fluid Mixtures,” filed Aug. 18, 2014; U.S. Application Ser. No. 62/074,703 titled “Doped Carbon Fibers and Carbon-Alloy Fibers and Method of Fabricating Thereof from Disparate-Molecular Mass Gaseous-, Liquid, and Supercritical Fluid Mixtures,” filed Nov. 4, 2014; and U.S. Application Ser. No. 62/074,739 titled “Method and Apparatus for Recording Information on Modulated Fibers and Textiles and Device for Reading Same,” filed Nov. 4, 2014, the entire contents of which are herein incorporated by reference.

### STATEMENT REGARDING FEDERALLY SPONSORED RESEARCH OR DEVELOPMENT

N/A

### BACKGROUND OF THE INVENTION

### Field of the Invention

The present invention is in the technical field of fiber and/or fibrous material production and specifically relates to the synthesis of ultra-high temperature materials (UHTMs) in fibrous forms/structures. Such “fibrous materials” can take various forms, such as individual filaments, short-shaped fiber, tows, ropes, wools, textiles, lattices, nano/microstructures, mesostructured materials, and sponge-like materials. In addition, four important classes of materials specifically relate to this invention: (1) carbon, doped-carbon and carbon alloy materials, (2) materials within the boron-carbon-nitride-X system, (3) materials within the silicon-carbon-nitride-X system, and (4) highly-refractory materials within the tantalum-hafnium-carbon-nitride-X system. All of these material classes offer compounds/mixtures that melt or sublime at temperatures above 1800° C.—and in some cases are among the highest melting point materials known (exceeding 3000° C.). In addition, the internal structure of the material within the fibrous form can be very important and enabling for many embodiments (and applications). For example, an individual filament can be a nanocomposite of more than one composition within these material classes. In some embodiments, this invention also relates even more specifically to the production of UHTM fibers, tows, ropes, textiles, lattices, and nano/microstructures that can be used to reinforce composite materials in extreme environments.

### Background on Carbon, Doped Carbon, and Alloyed Carbon Materials

The fabrication of carbon fibers for industrial purposes extends back (at least) to the time of Edison, John W. Starr, and Alexander Lodygin, who carbonized bamboo and paper fibers to create the first incandescent filaments. The bulk carbon fiber industry likely had its inception with the establishment of the National Carbon Company (NCC) in 1886, based in Cleveland, Ohio, later acquired by the Union Carbide Company (UCC). The NCC produced carbon for the manufacture of lighting carbons, carbon brushes for generators and motors, and carbon batteries, among other products. In the early 1960s, the Union Carbide Co. used rayon as a precursor to produce the first commercial carbon fiber. In the latter portion of the 20th century, various approaches were developed to produce high-strength carbon fibers from rayon, polyacrylonitrile (PAN), and Pitch. In these cases, carbon-bearing precursors are spun/drawn into long strands and subsequently stabilized/oxidized, carbonized, and (optionally) graphitized. While very high-strength-to-density fibers and fibrous materials can be created in this manner, the precursors employed must be synthesized and/or purified prior to use—and are relatively expensive. This is one factor that contributes to the cost of carbon fiber production today.

The strength of PAN/Pitch carbon fibers derives largely from the pre-alignment of the precursor molecules along the axis of the fibers, with carbonization at very small fiber cross-sections, to create a consistent microstructure over the cross-section of the fiber. In general, this approach provides fibers with graphitic planes running parallel to the fiber axis, mixed with some amorphous and fine-grained carbon phases. Note that these graphitic sheets provide great strength along the axis, but less so perpendicular to the fiber axis (as the graphitic planes can shear relative to each other), which leads to anisotropic properties of the fibers. This approach is also generally limited to small-diameter fibers to obtain the necessary uniformity and densification of the carbon material. Thus, untwisted filament bundles, or tows, of thousands of fibers are necessary to obtain large volume coverage with requisite quality, which also adds to the complexity and cost of carbon fiber production and use. In many applications, it would be preferable to use fewer high quality fibers that are of larger diameter, e.g. during the weaving of carbon fiber cloth, where useful strands could have diameters of up to 1-2 mm.

Current commercial production of carbon fiber does not produce fully-dense, void-free, and porosity-free fibers. For example, the range of density for high-strength PAN fibers is generally 1.80-1.94 g/cm³ and that for pitch fibers is generally 2.10-2.16 g/cm³—while for comparison, the theoretical density for crystalline graphite is 2.267 g/cm³. The difference between theory and the PAN/Pitch fibers is due to the presence of other forms of carbon and the voids/porosities present within the fibers. These voids/porosities lower the strength and toughness of the fibers. Unlike glassy carbon, which has a typical density of only about 1.5-1.6 g/cm³, these voids/porosities matter because they can easily propagate and lead to failure. In the case of glassy carbon, there is so much disorder that crack propagation is inhibited, which results in a material with greater toughness and stiffness (in a less dense material). Thus, the specific strength (i.e. strength/density) of a glassy-carbon fiber is on-par with that of the best commercial PAN or Pitch carbon fibers available today. And since carbon fiber is generally sought after for its specific strength over other materials, this leaves an important market niche for highly-uniform amorphous/glassy-carbon fibers, especially where they can be grown as larger diameter fibers.

One area of carbon fiber development that also remains relatively unexplored is the intentional introduction of dopants into carbon fibers to improve their mechanical, thermal, and/or electrical properties, as well as corrosion/oxidation resistance. Many instances related to doped carbon fiber involve the addition of various precursors to PAN, pitch, or other polymer strands, thereby incrementally-improving the fibers, while using existing methods of carbon fiber manufacture. In addition, some cases of doped carbon fibers exist, where dopant-bearing coatings are placed on the exterior of the fiber (or the fiber's precursor), and then baked to diffuse the dopants into the carbon fiber matrix. Three difficulties generally exist with these approaches: (1) diffusion of coated dopants toward the center of the carbon fiber takes a long time and is difficult to control; (2) these processes usually leave behind undesired impurities, as it is difficult to bake all the impurities out during carbonization; and (3) the extraction of impurities can leave the doped fiber with voids/porosities and in a less-densified state, which can potentially reduce strength of the fibers.

It is useful to dope carbon fibers if it can be done in a more uniform or controlled manner. First, dopants can be added that will provide improved conductivity (e.g. for lightning damage resistance). Second, dopants can be added to improve the strength and hardness of the fibers. Third, dopants can affect the microstructure of the fibers, e.g. by acting as nucleation sites that encourage the formation of fine-grained, amorphous, or glassy-carbon phases; this nucleation can limit the growth of undesired phases of carbon, such as graphitic planes that pass perpendicular to the fiber axis—which can otherwise make the fibers very brittle.

While carbon-fiber-based, carbon-matrix composites (C—C) are commonly used for many UHTM aerospace applications, within the atmosphere, C—C composites are limited by oxidation well below their ultimate sublimation temperatures. Oxidation of carbon begins at temperatures as low as 500° C. Thus, alternatives to C—C composites are desired, while maintaining very high melting points and retaining strength at temperature. Doping and alloying with other elements can potentially help inhibit the oxidation of carbon fibers.

### Background on Silicon-Carbon-Nitride System of Fibrous Materials

Within the Si—C—N system, Silicon carbide (SiC), silicon nitride (Si₃N₄), and silicon carbon nitride fiber-reinforced composites offer one alternative to C—C composites, and are desired for many aerospace applications due to their oxidation resistance and high-strength to weight ratios (specific strength).

Very often fibrous materials that contain compounds from the Si—C—N system are created by coating these materials onto other commonly-available fibers, e.g. carbon fiber. To our knowledge, there are very few examples of single composition homogeneous fibers, within the SiC—N system. Thus a method that can produce such homogeneous fibers would be highly valued.

### Background on Boron-Carbon-Nitride System of Fibrous Materials

Another alternative to carbon and Si—C—N high-temperature materials are materials within the boron-carbon-nitride system. This would include compounds, e.g. B₄C, BN, and B—C—N materials. Two highly valued materials within these compounds are cubic BN and BCN in the form of heterodiamond. While a great deal of research and development has been carried out on the synthesis of B—C—N coatings and powders, there are few processes for producing homogeneous uniform fibers within the B—C—N system.

### Background on Tantalum-Hafnium-Carbon-Nitride-based Fibrous Materials

To date, UHTM fiber-reinforcing materials with melting points above 3000° C. have been virtually non-existent. Some related materials have been offered in the trade; for example, boron-coated tungsten fiber and metal carbide-coated C-fibers for reinforcing composites.

In addition, the composition of the highest-melting point material has long been debated within the scientific community. There are three elements with melting points above 3270 K, namely W, Re, and C (graphite), and there are 12 binary compounds: HfB₂, HfC, HfN, TaC, TaB₂, TaN, ZrB₂, ZrC, NbC, TiC, BN, and ThO₂. Of these, HfC (at 4170 K) and TaC (at 4150 K) have the highest melting points. In the 1930s, the melting point of mixtures within the HfC—TaC system were measured and reported a record melting point of 4488 K, greater than either HfC or TaC. This UHTM appears to possess the highest melting point of any material known. In later studies, Ta4HfC5 was identified as having the greatest thermal stability (lowest vapor pressure) and lowest oxidation rate within the HfC—TaC system. A later melting point measurement for Ta₄HfC₅ reported a melting point of only 4263 K. It should be noted that in all cases, the measurements were made using samples obtained by hot-pressing HfC and TaC powders, and the composition of these mixtures was never confirmed to be fully dense or solid solutions. In fact, some variation with vapor pressure was noted, depending on the degree of compaction. Scientific controversy regarding the melting point of Ta₄HfC₅ continues to this day.

The production of UHTM materials is typically carried out by compaction of refractory carbide, boride, or nitride powders, where the powders have been synthesized by a variety of methods, e.g. electric arc processing, plasma processing, etc. Given the hardness and (usual) brittleness of these materials, it is difficult to create wire by drawing through dies, and given their high melting points, extrusion or melt spinning is also not possible. Instead, the base metal is usually drawn into wire and then carburized.

The problem with powder compaction is that the resulting sample is generally not fully dense; microscopic voids and cracks are often left within the sample. In addition, powders of differing composition do not fully mix to create a solid solution of uniform composition, making it more likely for grain growth and segregation to occur at high temperatures. As a result, fibers and wires of TaC, HfC, or Ta—Hf—C are brittle (when they can be made) and do not exhibit their full potential high-temperature stability/strength. The applicants are unaware of any commercial supplier of TaC, HfC, or Ta—Hf—C fiber or wire. Yet, such high temperature fiber/wire has many possible applications—if it could be made with uniform composition and without cracks/voids.

For example, space exploration and hypersonic applications require the use of UHTMs for both propulsion and re-entry. For this reason, durable, oxidation-resistant, high-melting-point materials have been sought for much of the last century—in the American, Soviet, and European space programs. During the cold war, UHTMs were required for the throat and expansion nozzles of ICBM rocket engines. Tungsten, rhenium, iridium, and niobium were initially used for this purpose, as they have varying degrees of oxidation resistance and have melting points of 3695 K, 3459 K, 2739 K, and 2750 K, respectively. Later, as composite materials became readily available, Carbon-Carbon rose into widespread use as it could temporarily withstand 3900 K, despite oxidation at temperatures above 500° C. During the space race, UHTMs were also required for ablative shielding on re-entry vehicles such as Apollo (a carbon/fiberglass phenolic), Soyuz (material undisclosed), and later the Space Shuttle (Carbon-Carbon). Finally, UHTMs were important for unconventional rocket technologies, e.g. nuclear thermal propulsion (NTP), where uranium fuel rods heated hydrogen directly. NTP rockets were limited in their theoretical efficiency by the maximum temperatures that could be reached within the engine core and hydrogen embrittlement of the fuel rods and cladding. Despite great progress in the United States during the Rover and NERVA programs, the ultimate UHTM that would allow molecular hydrogen to dissociate into atomic hydrogen was never fully realized (a UC—ZrC composite). This development would have given nuclear rockets an engine specific impulse (“ISP”) greater than 1000 seconds, making them a clear choice over conventional chemical rockets. For their part, the Soviets continued development of U-metal carbide composites in the 1980s, and claimed to have achieved temperatures sufficient for ISPs over 1100 seconds. The development of fibrous UHTM, could have led to many innovative ultra-high temperature composite materials for such aerospace applications, such as providing greater Isps, higher reentry velocities, and longer hypersonic flight times.

Fibrous UHTM also has potential utility for many more down-to-earth applications, such as field-emission tips, arc lamp filaments, high temperature reactors, combustion filters, furnace wall fiber reinforcements, extreme temperature insulation, and even archival paper.

### SUMMARY OF THE INVENTION

This invention relates to novel materials, specifically ultra-high temperature, high-strength refractory fibrous materials, which have previously not been realized, and their synthesis from gaseous, liquid, semi-solid, critical, and supercritical (precursor) fluid mixtures. Without limiting the overall scope of this invention, four important novel classes of UHTM materials specifically relate to this invention: (1) carbon, doped-carbon and carbon alloy materials, (2) materials within the boron-carbon-nitride-X system, (3) materials within the silicon-carbon-nitride-X system, and (4) highly-refractory materials within the tantalum-hafnium-carbon-nitride-X system. All of these material classes offer compounds/mixtures that melt or sublime at temperatures above 1800° C.—and in some cases are among the highest melting point materials known (exceeding 3000° C.). These materials are usually grown with some aspect ratio that is greater than 1:1 (length to diameter ratio) to distinguish them from powders and thin films. In this application, Applicant may at times refer to the material as a “fiber”, but it should be recognized that the term “fiber” includes “fibrous materials.” Note that such “fibrous materials” can take various forms, such as individual filaments, short-shaped fiber, tows, ropes, wools, textiles, lattices, nano/microstructures, mesostructured materials, and sponge-like materials.

It should be noted that the internal (crystalline) structure of the material within the fibrous form can also be very important and enabling for many embodiments and applications—and that our novel materials possess previously unrealized internal nano/microstructures, which provide novel bulk properties. For example, we have been able to synthesize nearly amorphous boron-carbon-nitride and silicon carbide fibers, and we have grown fine-grained Ta—Hf—C fibers; similarly fine-grained crystalline morphologies have not been previously realized. These quasi-amorphous and fine-grained fibers possess greater tensile strength than any known previously realized fibers/wires of similar composition. See examples in FIG. 19-24.

In addition, the fibrous materials are “grown” from precursor fluid mixtures that are decomposed locally at a reaction zone. Various means of decomposing the precursor can be used, e.g. applying focused laser beams, ion/atomic beams, electron/particle beams, electrical discharges, or combinations of the same, and a plurality of reaction zones are often created to synthesize many fibrous strands at once.

Unlike chemical vapor deposition (CVD) processes, where the heating occurs generally over a large area, micro-scale thermal deposition processes can occur in the presence of very large thermal gradients. These thermal gradients induce a strong thermal diffusion/Soret effect at/near the localized reaction zone, inducing a strong concentration gradient of species within the gas mixture. The decomposition reaction can occur by pyrolysis or photolysis, but is normally at least partially a thermally driven process; thus a thermal diffusion region can often be present, provided that the heating means is localized (e.g. a focused beam) and the surrounding vessel is substantially cooler.

We have found that the thermal diffusion effect greatly affects the decomposition pathways, composition, and nano/micro-scale crystal structure of the resulting fibrous materials, and that this gradient can be used to advantage. In particular, we have found that the use of highly-disparate molar mass precursors greatly enables the controlled growth of previously unobtainable novel materials—and has allowed us to synthesize many new fibrous UHTMs.

We have also found that by using highly disparate molar mass precursors, rapid fibrous material growth rates are possible well beyond those obtained through the use of a low molar mass precursor alone. In some cases, this has resulted in growth rates of one or two orders of magnitude beyond that expected for a given laser power and reaction vessel chamber pressure. And, by using highly disparate molar mass precursors, it is possible to dope or alloy materials with other elements/compounds in quantities, combinations, and distributions that cannot otherwise be realized. For example, to create a gadolinium-doped carbon fibrous material, with more gadolinium in the outer radius of the fibrous material, one can use tris(cyclopentadienyl)gadolinium(III) at 352.5 g/mol, (as a high molar mass precursor) to dope carbon grown from a low molar mass hydrocarbon, e.g. methane, at 16.0 g/mol. Carbon will dominate in the core of the fibrous material, while the concentration of Gadolinium can increase with radius.

It is generally understood that the term “thermal diffusion” refers to the concentration effect, which can occur in gases, while the Soret effect is commonly understood as referring to the concentration effect in liquids. Throughout this document, we will use the term “thermal diffusion” to refer to all instances of a thermally-induced concentration effect, regardless of the state of the fluids.

In one of its simplest forms, this invention uses one low molar mass (“LMM”) precursor, and one high molar mass (“HMM”) precursor, and employs the thermal diffusion/Soret effect to concentrate the LMM precursor at the reaction zone where a fibrous material is growing. It should be understood that the precursors do not necessarily have to be above or below a certain molar mass. Rather, the terms “LMM precursor” and “HMM precursor” are used to contrast the relative molar masses of the different precursors. The difference in molar mass of the precursors needs to be sufficient such that there is a substantive increase in the concentration of the LMM precursor at the reaction zone relative to the remainder of the chamber volume. Thus, a LLM precursor may have a relatively “high” molar mass so long as it is sufficiently lower than the HMM precursor molar mass to achieve the desired enhanced-concentration effect.

In this specification, we will assume that the term “molar mass” refers to the relative molar mass (mr) of each precursor species (i.e., relative to carbon-12), as determined by mass spectrometry or other standard methods of mr determination. As the invention relies on comparative measurements of substantively large differences in molar mass to obtain substantively enhanced growth rates of fibrous materials, the use of one method of molar mass determination versus another (or even different definitions of molar mass) will be virtually negligible in practice to the implementation of the invention. However, where the HMM or LMM species may be composed of a distribution of various species (e.g., for some waxes, kerosene, gasoline, etc.), the meaning of “molar mass” in this specification will be the mass average molar mass. Finally, it should be noted that this invention applies to both naturally occurring and manmade isotopic distributions of the molar mass within each precursor species.

In a preferred embodiment, for “highly disparate molar masses,” the molar mass of the HMM precursor is at least 1.5 times greater than the LMM, and can be substantially greater, on the magnitude of 3 or more times greater.

The HMM precursor, in addition, preferably possesses a lower mass diffusivity and lower thermal conductivity than the LMM precursor, and the lower diffusivity and thermal conductivity of the HMM precursor than the LMM precursor, the better. This makes it possible for the HMM precursor to insulate the reaction zone thermally, thereby lowering heat transfer from the reaction zone to the surrounding gases. The HMM precursor will also provide a greater Peclet number (in general) and support greater convective flow than use of the LMM precursor on its own. This enables more rapid convection within a small enclosing chamber, which in turn tends to decrease the size of the boundary layer surrounding the reaction zone, where diffusion across this boundary layer is often the rate limiting step in the reaction. At the same time, the thermal diffusion effect helps to maintain at least a minimal diffusive region over which a concentration gradient exists, allowing the LMM precursor to be the maintained at high concentration at the reaction zone. Note that the HMM precursor can be an inert gas, whose primary function is to concentrate and insulate the LMM precursor.

Thus, in some embodiments, this invention utilizes: (1) the thermal diffusion effect with highly disparate molar mass precursors so as to concentrate at least one of the precursors at the reaction zone and increase the reaction rate and/or improve properties of the resulting fibrous materials, (2) a means of maintaining the reaction zone within a region of space inside a reaction vessel, and (3) a means of translating or spooling the growing fibrous materials (or optics) at a rate similar to their growth rates so as to maintain the growing end of the fibrous material within the reaction zone—and thereby maintain a stable growth rate and properties of the fibrous material. Both short (chopped) fibrous materials may be grown, as well as long spooled fibrous materials. Methods are disclosed for growing and collecting short (chopped) fibrous materials, as well as spooling long fibrous materials as individual strands or as tows or ropes. During the growth of long fibrous material lengths, a fiber tensioner may also be provided to maintain the growing end of the fibrous materials from moving excessively within this reaction zone—and so that the spooling of the fibrous material does not misalign the fibrous material to the growth zone and interfere with their growth. There are a variety of ways to provide tension to a fibrous material known to those in the industry. However, we are the first to develop a means of tensioning a fibrous material without holding the end that is growing, while holding it centered in the reaction zone. We have developed electrostatic, magnetic, fluidic, and/or mechanical centering/tensioning means that can be both passively and actively controlled.

In various embodiments discussed herein, a pyrolytic or photolytic (usually heterogeneous) decomposition of at least one precursor occurs within the reaction zone. Decomposition of the LMM precursor may result in the growth of a fibrous material; however, it is also possible to use an LMM precursor that will react with the HMM precursor in the region of the reaction zone—where the LMM precursor would not yield a deposit of its own accord. Similarly, the HMM precursor can decompose to provide a deposit, either alone, or by reacting with the LMM precursor. And it is possible for the LMM precursor and the HMM to decompose, both providing deposit material. And, of course, it is possible to have multiple species of LMM and HMM precursors, that may each decompose or react with others.

As the by-products of the HP-LCVD reaction are always less massive than the precursors, the presence of a thermal diffusion region can lead to an excess of by-products and depletion of the precursors in the center of the reaction zone, effectively slowing the reaction rate along the center of the fibrous material axis (herein referred to as thermal diffusion growth suppression (TDGS)). This can greatly reduce the production rate of fibrous materials by HP-LCVD. This invention, in various embodiments, removes the TDGS, allowing much greater growth rates than are otherwise possible (by dispersing these by-products); for example: (1) changing the beam profile in real-time, (2) modulating the beam power, (3) using a pulsed laser, (4) applying a pulsed or continuous flow of gases across the reaction zone, (5) providing a secondary heating means, and/or (6) providing a “scavenger” species that will react to provide a more massive by-product, e.g. a scavenged byproduct (SBP) species—which will naturally leave the center of the reaction zone in the thermal gradient; this latter technique will be discussed more later. These methods can be used singly or in combination.

In some embodiments, another aspect of the invention is that more than one fibrous material can be grown in a controlled manner simultaneously. This can be effected through the use of a plurality of heating sources, e.g. an array of heated spots or regions. For example, an array of focus laser beams can be generated to initiate and continue fibrous material growth. We herein refer to a “primary” heating means(s) as the primary method of initiating and sustaining the growth zone. However, other sources of heating are also possible, such as through the use of induction heating of the fibrous materials, use of an array of electric arcs, etc. As described further below, more than one heating means can be used for each reaction zone.

Thus, in some embodiments, another aspect of this invention is that the thermal diffusion effect need not be induced solely by a primary heating means, but can be induced and controlled by another source of heat (i.e., a “secondary” heating means), thereby providing another parameter with which to drive and control the reaction rate and fibrous material properties. Where only the primary heating means is employed, the flow rate of precursors, pressure, and primary heating rate are the primary tools/parameters that can be used to control the reaction and fibrous material properties (e.g. diameter, microstructure, etc.). If another heating means is available to independently provide heat and control the thermal diffusion gradient and size of the thermal diffusion region, an important new tool is provided that can change the growth rate and properties of the fibrous materials independent of the primary heating means.

Now, it should be noted that temperature rises induced by the primary heating means(s) can vary from spot to spot across an array of heated spots, and this can produce undesirable variations in growth rates and/or fiber properties from fibrous material to fibrous material. For example, in the use of an array of focused laser beams there are often deviations in the spot to spot laser power of a few percent or more. In addition, variations in the spot waist of each laser spot induce a large variation in the temperature rise from spot to spot. Thus, even with precision diffractive optics or beam splitting, a laser spot array may yield a variation in peak surface temperature of over 20% from spot to spot. These variations must be either controlled electro-optically, or compensated through other means, or the fibrous material growth rates will not be similar and the fibrous material properties will vary. Where growth rates are substantially dissimilar, it becomes difficult to maintain a common growth front for many fibrous materials at once. In this case, some fibrous materials will lag behind, and if the growth front is not tracked actively, they may cease growing altogether once they leave their reaction zones.

So, whereas the primary heating means may be difficult or expensive to control dynamically, such as in the use of electro-optical modulation of many laser beams, a secondary heating means can be very simple—such as a resistive wire near, crossing, or around the reaction zone. Such a wire can be inexpensively heated by passing electric current through it from an amplifier and a data acquisition system that controls the temperature of the wire. Feedback of the thermal diffusion gradient and region size can be obtained optically with inexpensive CCD cameras, thereby allowing feedback control of the thermal diffusion region by modulating electric current passing to the wire. With existing technology, this can be implemented in a simple manner that is substantially less expensive than electro-optical modulation. This is especially true when attempting to grow many fibrous materials, such as hundreds or thousands of fibrous materials, at once. To yield a commercially viable textile or fibrous material tow (i.e., untwisted bundle of continuous filaments or fibrous materials) production system with thousands of fibrous materials via laser-induced primary heating means, where no secondary heating means is available, would be very expensive, whereas actively controlling thousands of current loops is relatively inexpensive and easy to implement. Thus, in some embodiments, the invention allows active control of a plurality of thermal diffusion regions (in order to control the growth and properties of fibrous materials) through the use of a secondary or tertiary heating means. Note that modulating the thermal diffusion region also changes the background temperature of the gases, which can also influence the growth rate and species present.

Further, in some embodiments, this invention goes beyond controlling only the thermal diffusion region within a given reaction zone, and provides virtual conduits for flow of LMM precursors from their inlet points within the vessel to each thermal diffusion region within the sea of HMM precursors. Heated wires can provide the flow conduits by creating a long thermal diffusion region throughout the length of each wire. These wires, if they are continued beyond the reaction zone, also provide a way to remove undesired byproducts from the reaction zone and prevent them from mixing substantially with the surrounding gases. Pressure-induced flows at the inlet/outlet point(s) of the virtual conduits can promote flow along these conduits to and beyond the reaction zone.

In addition, in some embodiments, the invention provides a means of modulating this flow of LMM precursors to each reaction zone by varying the temperature of locations along the heated wires, thereby providing a thermal diffusion valve that can increase or decrease flow of the LMM precursor to the reaction zone. For example, leads can branch off the heated wire to draw current elsewhere and lower the current through the remainder of the wire. Although traditional mass flow controllers and switching valves can be used, due to the length-scales involved, the response time of one preferred method (using heated wires as virtual flow conduits) is more rapid than that obtained through traditional mass flow controllers and switching valves that often contain large latent volumes. Switching times on the order of milliseconds or less can be effected, allowing for rapid control of properties.

During fibrous material growth from fluidic precursors, jets of heated gases (often by-products or precursor fragments) can sometimes be seen leaving a heated reaction zone. In one embodiment, heated wires emanating from the reaction zone(s) can channel these heated gases away from the reaction zone(s) and fibrous material tip, in desired directions, allowing more rapid growth.

In another embodiment, the wires/filaments/electrodes used to control the thermal diffusion region can also be charged relative to the fibrous materials being grown to generate a (high-pressure) discharge between the fibrous materials and the wires/filaments/electrodes. Electrostatics and electromagnetics can be used to channel precursor(s), intermediate(s), and by-product species to/from the fibrous material and/or to thermal diffusion channels.

In various embodiments, the systems, methodologies, and products described in U.S. application Ser. No. 14/827,752 titled “Method and Apparatus of Fabricating Fibers and Microstructures from Disparate Molar Mass Precursors,” filed Aug. 17, 2015, and incorporated by reference herein, can be utilized. However, for brevity, much of the disclosure contained in U.S. application Ser. No. 14/827,752 is not repeated here. It should be noted that the various embodiments and methods disclosed therein, can be utilized in connection with the present disclosure, including but not limited to those aspects related to (1) recording information on modulated fibers, microstructures and textiles and device for reading same, (2) functionally-shaped and engineered short fiber and microstructure materials, and (3) beam intensity profiling and control of fiber internal microstructure and properties.

In some aspects, the invention relates to the fabrication of fibrous materials of doped-carbon and carbon alloys/mixtures of the form C—X, or C—X—Y, where X and Y can be another element, but where carbon is the dominant element. In this patent application, the word “dopant” means the intentional addition of at least one element into carbon, where that element may or may not be chemically bound with the carbon. The invention can further include those doped-carbon and carbon alloys/mixtures fabricated from gaseous, liquid, semi-solid, critical, and supercritical fluid mixtures, wherein the mixture is comprised of at least two precursors with highly disparate molar masses. This mixture preferably possesses at least one carbon-bearing precursor and at least one dopant-bearing precursor, or a single precursor that carries both carbon and dopant but that is used with another HMM or LMM precursor.

In some aspects, the invention relates to the fabrication of fibrous materials within the boron-carbon-nitrogen-X system, where X can be another element. This includes B—C, B—N, C—N, and B—C—N compounds, alloys, and mixtures. The invention can further include those boron-carbon-nitride-X materials fabricated from gaseous, liquid, semi-solid, critical, and supercritical fluid mixtures, wherein the mixture is comprised of at least two precursors with highly disparate molar masses.

In some aspects, the invention relates to the fabrication of fibrous materials within the silicon-carbon-nitrogen-X system, where X can be another element. This includes Si—C, Si—N, C—N, and Si—C—N compounds, alloys, and mixtures. The invention can further include those boron-carbon-nitride-X materials fabricated from gaseous, liquid, semi-solid, critical, and supercritical fluid mixtures, wherein the mixture is comprised of at least two precursors with highly disparate molar masses.

In some aspects, the invention relates to the fabrication of fibrous materials within the tantalum-hafnium-carbon-nitrogen-X system where X can be another element. This includes Ta—C, Ta—N, Hf—C, Hf—N, Ta—C—N, Hf—C—N, Ta—Hf—C, Ta—Hf-N, and Ta—Hf—C—N compounds, alloys, and mixtures. The invention can further include those tantalum-hafnium-carbon-nitrogen-X materials fabricated from gaseous, liquid, semi-solid, critical, and supercritical fluid mixtures, wherein the mixture is comprised of at least two precursors with highly disparate molar masses.

In various embodiments, these four classes of fibrous materials exhibit (1) amorphous, glassy, vitreous, random non-crystalline, or quasi-crystalline (“RNQ”) morphologies, wherein no apparent long-range order exists at length scales of 35 nm or above; or (2) nanocrystalline morphologies, with grain sizes smaller than 100 nm; or (3) crystalline ultra-fine-grained morphologies, with grain sizes between 100-500 nm; or (4) crystalline, fine-grained morphologies with grain sizes smaller than 5 microns. By possessing highly-refined grain morphologies, these fibrous materials are stronger and tougher than any existing commercial fibrous materials of the same composition. In various embodiments, where carbon is the dominant species in the fibrous material, RNQ morphologies possessing amorphous carbon, diamond-like carbon, hydrogenated diamond-like carbon, or tetrahedrally-bonded amorphous carbon have also been realized.

In various embodiments single-crystal “whisker-like” fibrous materials can be produced of these materials, under specific conditions. These whiskers are useful as fiber reinforcement, as they can possess extremely high tensile strengths, often exceeding any polycrystalline material of the same composition.

In various embodiments, these four classes of materials can also be grown with homogeneous single-phase isotropic compositions and morphologies, or as material blends with compositions distributed radially or axially (or both) along the fibrous forms.

In one embodiment, a fibrous material comprising carbon and at least one additive element is provided, wherein the concentration of carbon is at least 55 atomic percent, and wherein said fibrous material is grown in at least one localized reaction zone from gaseous, liquid, semi-solid, critical, or supercritical precursor fluid mixtures using at least one primary heating means. As the atomic percent will always total 100, in this embodiment, if the concentration of carbon is 60 atomic percent, the one or more additive elements will total 40 atomic percent.

The “additive element” can be a dopant, alloying, or mixture element that is added to adjust the properties of the base compounds described herein, and in the claims. Without limiting the scope of potential additive elements that might be appropriate for various base compounds, potential additive elements can include lithium, beryllium, boron, nitrogen, oxygen, fluorine, magnesium, aluminum, silicon, phosphorous, sulphur, chlorine, scandium, titanium, vanadium, chromium, manganese, iron, cobalt, nickel, copper, zinc, gallium, germanium, selenium, bromine, yttrium, zirconium, niobium, molybdenum, technetium, ruthenium, rhodium, palladium, silver, cadmium, indium, tin, antimony, tellurium, iodine, lanthanum, cerium, praseodymium, neodymium, promethium, samarium, gadolinium, terbium, dysprosium, holmium, erbium, thullium, Ytterbium, hafnium, tantalum, tungsten, rhenium, osmium, iridium, platinum, gold, mercury, lead, bismuth, actinium, thorium, uranium, neptunium, plutonium, americium, curium, and californium.

In various embodiments comprising carbon and at least one additive element, the fibrous material can be glassy carbon, vitreous carbon, amorphous carbon, quasi-crystalline carbon, nanocrystalline carbon, diamond-like carbon, tetrahedrally-bonded amorphous carbon, turbostratically-disordered carbon, pyrolytic graphite, graphite, graphite aligned parallel to the fiber axis, graphene, graphene aligned parallel to the fiber axis, carbon nanotubes, carbon nanotubes aligned parallel to the fiber axis, fullerenes, carbon onions, diamond, lonsdaleite, and carbyne.

In some embodiments, the fibrous material are comprised of one or more fibers having a length to diameter aspect ratio of at least 3:1. Additionally, the fibrous materials can take a variety of forms, including single fiber strand, many fiber strands, short-shaped fibers, an array of fibers, tows, ropes, fabrics, textiles, wools, lattices, nano/microstructures, mesostructured materials, and sponge-like materials.

In some embodiments, the fibrous materials can have varying internal crystalline structures, including but not limited to (a) amorphous, glassy, vitreous, random non-crystalline, or quasi-crystalline morphologies, wherein no apparent long-range order exists at length scales of 35 nm or above; (b) nanocrystalline morphologies, with grain sizes smaller than 100 nm; (c) crystalline ultra fine-grained morphologies, with grain sizes between 100-500 nm; (d) crystalline, fine-grained morphologies with grain sizes smaller than 5 microns; and (e) single crystal(s).

In some embodiments using the localized reaction zones, there is also at least one thermal diffusion region at or near the localized reaction zone, wherein said thermal diffusion region is at least partially controlled by a secondary heating means. In various embodiments, the precursor fluid mixtures comprise a mixture of low molar mass and high molar mass precursors.

In some embodiments, the fibrous material comprises at least a first element and a second element, wherein said first element is at least one of silicon, carbon, and boron, and wherein said second element is different from the first element and at least one of silicon, carbon, boron, nitrogen, and an additive element, and wherein the concentration of nitrogen, if present, is no greater than 67 atomic percent, and the concentration of the additive element, if present, is no greater than 35 atomic percent, and wherein said fibrous material is grown in at least one localized reaction zone from gaseous, liquid, semi-solid, critical, or supercritical precursor fluid mixtures using at least one primary heating means. Again, the total atomic percent of the fibrous material will total 100 atomic percent. There are multiple various sub-embodiments within this type of fibrous material, including:
(a) where the first element is boron and said second element is carbon, and further comprising nitrogen and, optionally, at least one additive element, wherein the concentration of boron is no greater than 95 atomic percent, the concentration of carbon is no greater than 95 atomic percent, the concentration of nitrogen is no greater than 67 atomic percent, and the concentration of the at least one additive element, if present, is no greater than 35 atomic percent. In this situation, the fibrous material can have a variety of internal crystalline structures, including but not limited to cubic internal crystalline structure, internal crystalline structure of heterodiamond, rhombohedral-like internal crystalline structure of B₄C;
(b) where the concentration of boron is between 20-30 atomic percent, the concentration of carbon is between 45-55 atomic percent, the concentration of nitrogen is between 20-30 atomic percent, and the concentration of the at least one additive element is no greater than 15 atomic percent;

(c) where first element is silicon and said second element is carbon, and further comprising nitrogen and, optionally, at least one additive element, wherein the concentration of silicon is no greater than 95 atomic percent, the concentration of carbon is no greater than 95 atomic percent, the concentration of nitrogen is no greater than 67 atomic percent, and the concentration of the at least one additive element, if present, is no greater than 35 atomic percent;

(d) where the first element is silicon and said second element is carbon, and, optionally, further comprising at least one additive element, wherein the concentration of silicon is between 45-55 atomic percent, the concentration of carbon is between 45-55 atomic percent, and the concentration of the at least one additive element, if present, is no greater than 10 atomic percent;

(e) where the first element is silicon and said second element is carbon, and, optionally, further comprising at least one additive element, wherein the concentration of silicon is between 22-43 atomic percent, the concentration of carbon is between 57-77 atomic percent, and the concentration of the at least one additive element, if present, is no greater than 21 atomic percent;

(f) where the first element is silicon and said second element is nitrogen, and, optionally, further comprising at least one additive element, wherein the concentration of silicon is between 32-52 atomic percent, the concentration of nitrogen is between 47-67 atomic percent, and the concentration of the at least one additive element, if present, is no greater than 21 atomic percent; and

(g) where the first element is silicon and said second element is boron, and, optionally, further comprising at least one additive element, wherein the concentration of silicon is between 7-33 atomic percent, the concentration of boron is between 33-94 atomic percent, and the concentration of the at least one additive element, if present, is no greater than 15 atomic percent.

In some embodiments, the fibrous material comprises at least a first element and a second element, wherein said first and second elements are at least two of tantalum, hafnium, carbon, boron, nitrogen and an additive element, and wherein the concentration of nitrogen, if present, is no greater than 67 atomic percent, and the concentration of the additive element, if present, is no greater than 67 atomic percent, and wherein said fibrous material is grown in at least one localized reaction zone from gaseous, liquid, semi-solid, critical, or supercritical precursor fluid mixtures using at least one primary heating means. Again, whatever combination is used, the total atomic percent of the fibrous material will be 100 atomic percent. There are multiple various sub-embodiments within this type of fibrous material, including:
(a) where the first element is tantalum and said second element is hafnium, and further comprising carbon and, optionally, at least one additive element, wherein the concentration of tantalum is no greater than 95 atomic percent, the concentration of hafnium is no greater than 95 atomic percent, and the concentration of carbon is between 5-67 atomic percent, and the concentration of the at least one additive element, if present, is no greater than 35 atomic percent;
(b) where the first element is tantalum and said second element is hafnium, and further comprising carbon, wherein the concentration of tantalum is between 35-45 atomic percent, the concentration of hafnium is between 5-15 atomic percent, and the concentration of carbon is between 45-55 atomic percent; and
(c) where the first element is hafnium and second element is carbon, further comprising nitrogen and, optionally, at least one additive element, wherein the concentration of hafnium is no greater than 95 atomic percent, the concentration of carbon is no greater than 95 atomic percent, the concentration of nitrogen is between 5-67 atomic percent, and the concentration of the at least one additive element, if present, is no greater than 35 atomic percent.

In some embodiments, a method of fabricating ultra high temperature fibrous materials is provided. Thus, in some embodiments, the method comprises introducing a low molar mass precursor species and a high molar mass precursor species into a reaction vessel, said high molar mass precursor having a molar mass substantively greater than the low molar mass precursor species, and creating at least one localized reaction zone by a primary heating means, wherein at least partial decomposition of at least one said precursor species occurs in said reaction zone, and establishing at least one thermal diffusion region at or near said reaction zone, said thermal diffusion region controlled at least in-part by a secondary heating means, and wherein said thermal diffusion region creates a concentration gradient of said low molar mass precursor species and said high molar mass precursor species, and growing a ultra high temperature fibrous material at or near the reaction zone.

In various embodiments of the method, the precursor species contain at least one ultra-high-temperature element or compound. The term “ultra-high-temperature” materials, elements and compounds means, or is characterized by, materials/elements/compounds/mixtures that melt or sublime at temperatures above 1800° C. The precursor species can be in a variety of forms, including but not limited to gaseous, liquid, semi-solid, critical, or supercritical precursor state at or near said reaction zone.

As described above, in some embodiments of the method, the fibrous material is comprised of one or more fibers, wherein said fibers each have a length to diameter aspect ratio of at least 3:1, wherein said fibers each have a first end and a second end, said first ends being in or at said reaction zones during their growth. In some embodiments, the fibers are translated or spooled backwards as they are grown to maintain said first ends within said reaction zone during their growth. In other embodiments, the reaction zone is translated as said first end of said fiber grows to maintain said first end within said reaction zone during their growth. As with the fibrous material embodiments, the fibrous materials grown using the disclosed methods can take a variety of forms, including but not limited to a single fiber strand, many fiber strands, short-shaped fibers, an array of fibers, tows, ropes, fabrics, textiles, wools, lattices, nano/microstructures, mesostructured materials, and sponge-like materials.

### BRIEF DESCRIPTION OF THE DRAWINGS

It should be noted that identical features in different drawings are generally shown with the same reference numeral. Various other objects, features and attendant advantages of the present invention will become fully appreciated as the same becomes better understood when considered in conjunction with the accompanying drawings.

FIG. 1 shows a thermal diffusion region, reaction zone, fibrous material, and presence of LMM precursor and HMM precursor of one embodiment of the invention.

FIG. 2 is one embodiment of the invention showing an array of thermal diffusion zones, reaction zones, and fibrous materials, together with fibrous material tensioners and spooling device/mandrel.

FIG. 3 is one embodiment of the invention showing precursors flowed co-axially toward the reaction (or growth) zone.

FIG. 4 is one embodiment of the invention showing precursors flowed in planar sheets toward the reaction (or growth) zones and an array of fibrous materials.

FIG. 5 is one embodiment of the invention depicting a two-phase (e.g. a gas+liquid) system, having two thermal diffusion regions around each fibrous material.

FIG. 6 is one embodiment of the invention depicting a two-phase (e.g. fluid+fluid/solid) system, having two thermal diffusion regions around each fibrous material.

FIG. 7(a) shows one embodiment of the invention using a solid source of HMM precursor.

FIG. 7(b) shows one embodiment of the invention using a liquid source of HMM precursor.

FIG. 8(a) shows one embodiment of the invention using a primary heating means and secondary heating means, namely a wire, having a partial loop.

FIG. 8(b) shows one embodiment of the invention using a primary heating means and secondary heating means, namely a wire, having coils.

FIG. 9(a) shows one embodiment of the invention using a wire near or in front of an array of growing fibrous materials.

FIG. 9(b) shows one embodiment of the invention using a wire manifold and individual wires that can be modulated.

FIG. 10 shows one embodiment of the invention having a series of wires near or in front of a fibrous material.

FIG. 11 shows a flow diagram of one embodiment of the invention.

FIG. 12 shows one embodiment of the invention using a baffle.

FIG. 13 is a graph showing how the use of HMM and LMM precursors can be used to advantage to obtain greater growth rates.

FIG. 14 shows an example of one embodiment showing a combination of profiles, shapes, and geometric orientations of a fibrous material within a matrix.

FIG. 15 shows a smooth fibrous material with local smoothness <100 nm per 5 microns.

FIGS. 16(a)-(c) show material blends and anisotropic blends in accordance with one embodiment of the invention.

FIG. 17 shows a branched fibrous material in accordance with one embodiment of the invention.

FIGS. 18(a)-(b) show zigzag-shaped fibrous materials in accordance with one embodiment of the invention.

FIG. 19 shows an example of a boron-carbon-nitride fiber grown using this invention, together with an EDS spectra of its composition.

FIG. 20 shows an example of a Si—C fiber being grown using a focused laser beam as the primary heating means.

FIG. 21 shows an example of a pure Ta—Hf—C fiber grown using this invention.

FIG. 22 shows an example of a pure single-crystal refractory tungsten fibrous material grown by high pressure laser chemical deposition in accordance with one embodiment of the invention.

FIG. 23 shows a tungsten-doped silica fiber grown using this invention.

FIG. 24 shows a carbon-doped silica fiber grown using this invention.

FIG. 25 shows C—Si fiber with a 3:2 ratio of carbon to silicon, and shows tensile strengths of 6-9 GPa.

FIG. 26 shows a tensile test graph of the fiber of FIG. 25.

### DETAILED DESCRIPTION OF THE INVENTION

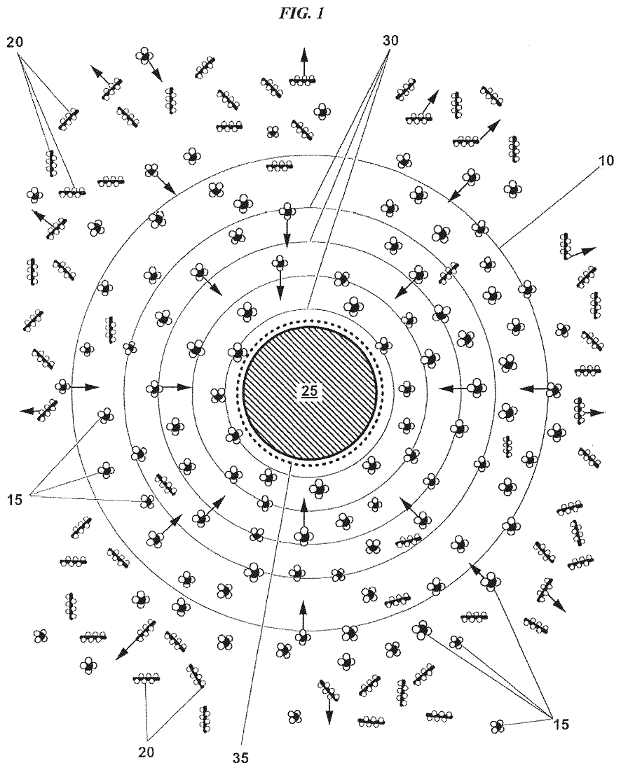

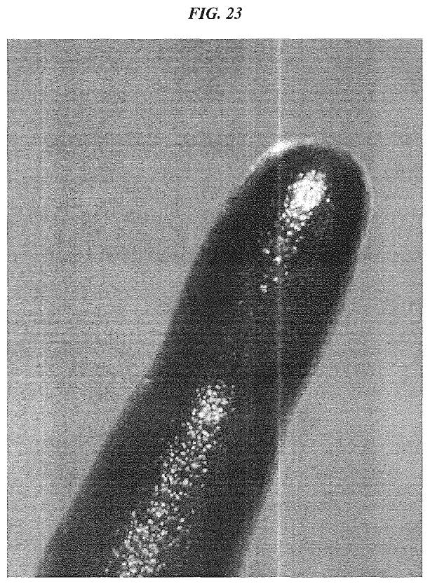

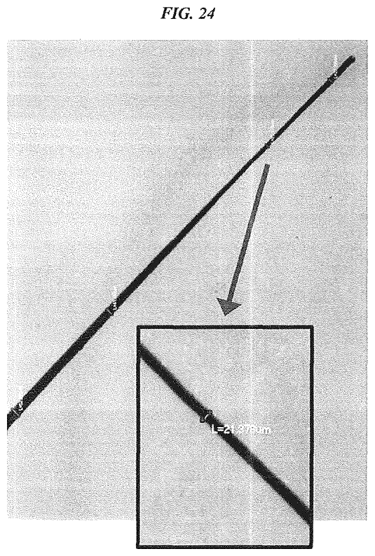

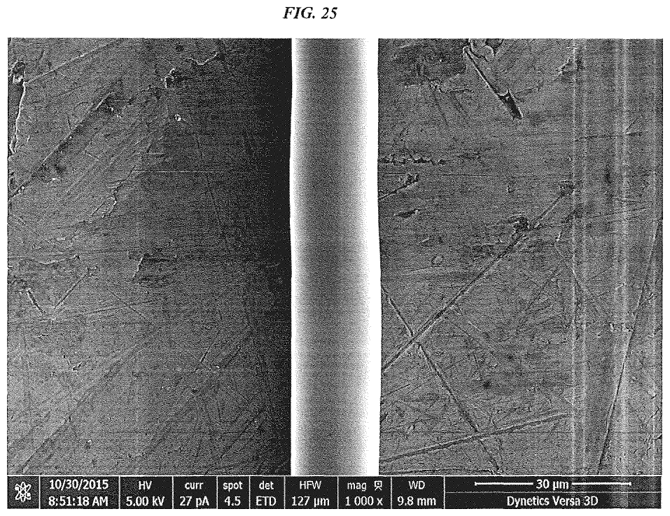

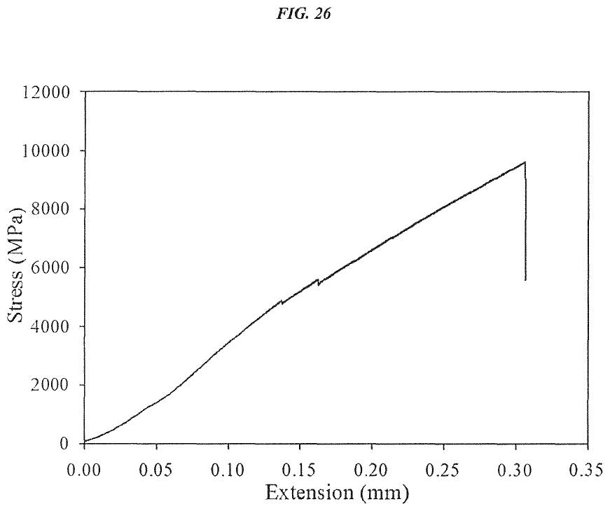

FIGS. 1 through 26 illustrate various views and embodiments of the present invention, and supporting graphs and data. Various embodiments may have one or more of the components outlined below.

FIG. 1 depicts a thermal diffusion region (sometimes also referred to as a “thermodiffusion region”) 10 surrounding a fiber or fibrous material 25, showing the concentration gradient 30 that occurs when a mixture of two highly disparate molar mass precursors are mixed together near the fiber or fibrous material 25. The concentration gradient 30 is not shown in all the figures. The LMM precursors 15 (usually) tend to concentrate at the region of greatest temperature, which in this case surrounds the reaction zone (sometimes also referred to as the growth zone) 35. The HMM precursor 20 species (usually) tend to be displaced away from the reaction zone 35 at the outside of the thermal diffusion region 10, and as a result, tend to thermally insulate the reaction zone 35. As depicted in FIG. 1, some LMM precursor 15 may exist outside of the thermal diffusion region 10, and some HMM precursor 20 may exist in the thermal diffusion region 10. In addition, it should be noted that those of skill in the art recognize that there is often not a well-defined boundary where the thermal diffusion region 10 ends, but that the concentration gradient 30 may taper off gradually.

One aspect of some embodiments of this invention is that the reaction zone 35 is thermally insulated by the HMM precursor 20, thereby greatly reducing heat losses to the surrounding fluids. Much greater growth rates have been observed with vastly reduced input to the power of the primary heating means 40. Thus, one aspect of the invention's utility is that it makes the growth of many fibers or fibrous materials 25 at once much more efficient and feasible. For example, in the growth of 10,000 fibrous materials at once, where each heated spot receives 200 mW of incident power (as is common in traditional laser induced fibrous material growth), the total energy entering the vessel will be 2 kW. This substantial heat budget must be dealt with or the temperature in the surrounding gases will rise over time. This invention greatly decreases the power required at each reaction zone 35. Thus, for example, where only 40 mW may be required at each reaction zone 35 with the HMM precursor 20 and LMM precursor 15 mixture, the total energy entering the vessel is now only 400 W, which requires significantly less external cooling and provides energy savings making the process more economically viable.

Note that to prevent excessive homogeneous nucleation, the gases in the thermal diffusion regions 10 may generally be at a lower temperature than the threshold for rapid (complete) decomposition of the precursors, but this is not required. Since the thermal diffusion regions 10 and reaction zones 35 overlap close to the growing fiber or fibrous material 25, the thermal diffusion regions 10 may exceed this temperature. In some cases, it may even be useful to induce homogeneous nucleation to provide fresh nucleation sites at the fiber or fibrous material 25 tip, and this invention can provide an extended heated region where this can occur.

The reaction takes place inside a reaction vessel, which is any enclosure that will contain the precursors for the desired life of the system and withstand any heat from the primary or secondary heating means(s) 40 or 110. The reaction vessel may be rigid or flexible. For example, the reaction vessel could be lithographically-patterned microfluidic structures in silicon, a molded polymeric balloon, a glass-blown vessel, or a machined stainless steel chamber—there are many possible means to implement the vessel/enclosure. The reaction vessel may include any number of pressure controlling means to control the pressure of the reaction vessel. Non-limiting examples of pressure controlling means include a pump, a variable flow limiter, a piston, a diaphragm, a screw, or external forces on a flexible reaction vessel (that change the reaction vessel internal volume), or through the introduction of solids that also effectively change the available internal volume (e.g., the introduction of HMM precursor 20 in solid form). The source of precursors and/or reaction vessel may be heated to maintain a particular partial pressure of the precursors during growth, and to maintain the vessel windows clear of condensed precursor(s) that can block the window transmissions.

As described further herein, the precursors can be introduced in a wide variety of different ways and configurations. As non-limiting examples, the LMM precursor 15 and HMM precursor 20 can be: (1) flowed jointly (pre-mixed) into the reaction vessel; (2) flowed co-axially and directed at a reaction zone(s); (3) flowed in alternating sheets and directed at a reaction zone(s); (4) flowed from alternating sources and directed at a reaction zone(s); (5) flowed from separate sources and directed tangential to the reaction zone; and (6) flowed from separate sources and directed at an angle relative to each other.

A wide variety of different LMM precursors 15 and HMM precursors 20 can be employed in combination in order to obtain the desired thermal diffusion region and controlling effects. For example, for silicon carbide deposition, silane and methane can be used as LMM precursor 15 gases, while HMM precursor 20 gases such as tetraiodosilane, SiI₄, or Octadecane, C₁₈H₂₈, can be used. This list is not intended to be exhaustive, and it is only for explanatory purposes.

Importantly, it is the substantive difference in mass and/or diffusivity that is important to achieve the best results, rather than the individual molar masses of the molecules, so that any of the above mentioned HMM precursors, for example, could be used as an LMM precursor, provided another HMM precursor of substantively greater mass were used with it. Other examples of LMM precursors 15 and HMM precursors 20 are also outlined in the cross-referenced applications, including U.S. Application Ser. No. 62/074,703, incorporated by reference herein.

The HMM precursor 20 species can be introduced as gases, liquids, critical/supercritical fluids, solids, semi-solids, soft plastic solids, glassy solids, or very viscous liquids. Depending on the precursor chosen, the HMM precursor 20 may liquefy, evaporate, or sublime near the reaction zone(s) 35. The HMM precursor 20 species can vary widely depending on the type of fibrous material being produced. As non-limiting examples, HMM precursors 20 can be silanes, boranes, hydronitrogen compounds, nitrogen substituted hydrocarbons and aromatic compounds, metal hydrides, organometallics, organo-silicon species, organo-boron species, metal halides, hydrocarbons, fluorocarbons, chlorocarbons, iodocarbons, bromocarbons, or halogenated hydrocarbons—as individual species or mixtures thereof. The HMM precursor 20 may also be inert and not decompose, or have very limited decomposition, at the reaction zone 35. The HMM precursor 20 may also physically or chemically inhibit the formation of clusters and particulates near the reaction zone(s) 35.

Similar to the HMM precursors 20, the LMM precursor 15 species can vary widely depending on the type of fibrous material being produced, and can be introduced as gases, liquids, critical/supercritical fluids, solids, semi-solids, soft plastic solids, glassy solids, or very viscous liquids. As non-limiting examples, LMM precursors 15 can be hydrogen, nitrogen, ammonia, silanes, boranes, hydronitrogen compounds, nitrogen substituted hydrocarbons and aromatic compounds, metal hydrides, organometallics, organo-silicon species, organo-boron species, metal halides, hydrocarbons, fluorocarbons, chlorocarbons, iodocarbons, bromocarbons, or halogenated hydrocarbons—as individual species or mixtures thereof. Depending on the HMM precursor 20 and the LMM precursor 15, the LMM precursors 15 may (a) react with at least one HMM precursor 20, causing the LMM precursor to deposit, or partially decompose, such that a new “derived precursor species” will be formed and will be concentrated at the reaction zone(s) 35 (and this derived precursor decomposing, resulting in the growth of the fibrous material); or (b) act as a catalyst that decomposes the HMM precursor 20 to a derived precursor species (having a lower molar mass than the HMM precursor) that will be concentrated at the reaction zone(s) 35 (and this derived precursor species decomposing, resulting in the growth of the fibrous material).

Depending on the desired fibrous material characteristics, and HMM precursor 20 and LMM precursors 15 used, the precursors can be in a variety of states. For example: (1) the precursors can all be in a gaseous state; (2) the precursor(s) concentrated at the reaction zone 35 may be in a gaseous state while the precursor(s) outside of the reaction zone 35 are in a critical, liquid, or solid state; (3) the precursor(s) concentrated at the reaction zone 35 may be at the critical point while precursor(s) outside of the reaction zone 35 are in a liquid or solid state; (4) the precursor(s) concentrated at the reaction zone 35 may be in a supercritical state, while precursor(s) outside of the reaction zone 35 are in a supercritical, critical, liquid, or solid state; (5) all precursors are at the critical point or are in the supercritical fluid state, or (6) the precursor(s) concentrated at the reaction zone 35 may be in a liquid state while the precursor(s) outside of the reaction zone 35 are in a liquid or solid state. Of course, this is not intended as an exhaustive list. The “liquid” state above can include very viscous liquids or glasses, while the “solid” state can include soft plastic solids or semisolids. Note that the LMM and/or HMM precursors can change state as they approach the thermal diffusion region(s) and/or reaction zone(s), and that the precursors may even “wick” from a precursor that is a liquid, critical/supercritical fluid, solid, semi-solid, soft plastic solid, glassy solid, or very viscous liquid—into the reaction zone(s) using a “wicking means, to be described below.

In some embodiments, an intermediate molar mass (“IMM”) precursor may also be introduced into the reaction vessel. Depending on the fibrous material desired, and the LMM precursor 15 and HMM precursor 20 used, an IMM precursor may be introduced to further separate, react with, or break down the LMM precursor 15 and/or HMM precursor 20. For example, where the HMM precursor is hexadecane (C₁₆H₃₄34) [molar mass=226.45 g/mol] and the LMM precursor is methane (CH₄) [molar mass=16.04 g/mol], an IMM precursor such as carbon tetrafluoride (CF₄) [molar mass=88.00 g/mol] can be added to react with both the methane and hexadecane, to produce a carbon fibrous material product and hydrogen+hydrogen fluoride by-products. In some embodiments, the IMM precursor is introduced to primarily react with, and break down, the HMM precursor 20 species. For example, where the HMM is icosane (C₂OH₄₂) [molar mass=282.56 g/mol] and the LMM is silane (SiH4) [32.12 g/mol], an IMM precursor such as bromine (Bra) [molar mass=159.80 g/mol] can be introduced to react with the hydrogen in the icosane to produce carbon as a product (i.e., deposited as part of the fibrous material) and hydrogen bromide as a byproduct. While the silane, concentrated at the center of the thermal diffusion region will deposit spontaneously at low temperatures without bromine being present, the decomposition of icosane is enhanced through the reaction with bromine. Generally, the molar mass of the IMM precursor is between that of the LMM precursor and HMM precursor.

Just as examples, and not as limitations, the following types of fibrous materials can be fabricated using the system and methods described herein: boron, boron nitride, boron carbide, boron carbon nitride, carbon, doped-carbon, carbon nitride, aluminum carbide, aluminum nitride, aluminum oxide, aluminum oxynitride, silicon carbide, silicon nitride, silicon carbon nitride, silicon boride, silicon boron carbide, silicon boron nitride, silicon oxide, silicon oxynitride, carbon silicon oxide, carbon silicon nitride, nickel, iron, titanium, titanium carbide, tantalum carbide, hafnium carbide, tantalum hafnium carbide, tungsten, tungsten carbide, tungsten silicon oxide fibrous materials, to name just a few. And these materials can be doped with a wide variety of other elements/compounds. Other examples are outlined in the cross-referenced applications, including U.S. Application Ser. No. 62/074,703, incorporated by reference herein.

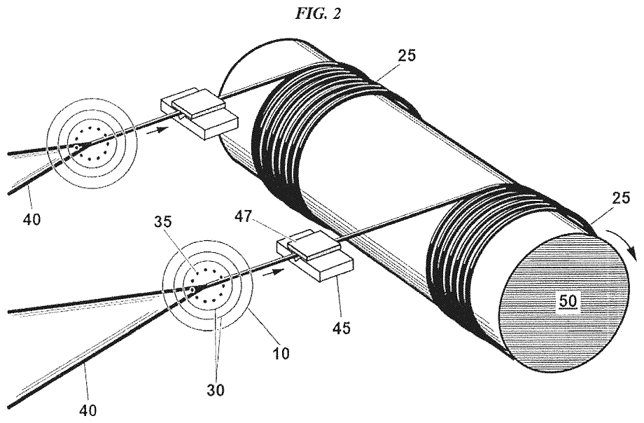

FIG. 2 depicts one embodiment of the invention; which includes an array of thermal diffusion regions 10, reaction zones 35, primary heating means 40, tensioners 45, a tension adjustment device 47, and a spooling device/mandrel 50. The primary heating means 40 is applied to create the reaction zone 35 and thermal diffusion region 10. The spooling device/mandrel 50 rotates to wind the grown fibers or fibrous materials 25 onto the spooling device/mandrel 50. Individual spooling devices/mandrels 50 could be used for each fiber or fibrous material 25, or many fibers or fibrous materials 25 can be wound onto a single spooling device/mandrel 50 to create tow. While shown as an array of growing fibers or fibrous materials 25, a similar configuration could be used for growing a single fiber or fibrous material 25. The optional tensioners 45 can be used to add sufficient tension and alignment to the fibers or fibrous materials 25 as they are wound on the spooling device/mandrel 50. Other methods for gathering fibers or fibrous materials 25 are known to those of skill in the art. However, we have developed new methods of tensioning the fibrous material without holding the end that is growing, while maintaining it centered in the reaction zone. We have developed electrostatic, magnetic, fluidic, and/or mechanical centering/tensioning means that can be both passively and actively controlled.

Note that the primary heating means 40 can be any number of options known to those of skill in the art able to create localized reaction zone(s) 35 and thermal diffusion region(s) 10 (either alone or in combination with other primary heating means). As non-limiting examples, primary heating means 40 may be one or more focused spots or lines of laser light, resistive heating (e.g., passing electrical current through contacts on the fibrous material), inductive heating (e.g. inducing current in the fibrous material by passing current through coiled wires near or surrounding the fibrous material), high pressure discharges (e.g. passing current through the precursors from electrodes to the fibrous materials), focused electron beams, focused ion beams, and focused particle bombardment (e.g. from a particle accelerator). For reference, radiative primary heating means 40 can also use soft X-ray, ultraviolet, visible, infrared, microwave, millimeter-wave, terahertz, or radio frequency radiation (e.g. within electromagnetic cavities) to create reaction zones. The primary heating means 40 in FIG. 2 are focused laser beams.

Secondary heating means are not shown explicitly in FIG. 2, but could be used. As described previously, secondary heating means 110 allow further control and enhancement of the thermal diffusion region 10. This, in turn, allows the real-time modulation and control of the concentration of LMM precursor 15 species at the reaction zone 35, and hence real-time modulation and control of fibrous material geometry and material properties. As non-limiting examples, secondary heating means 110 may be energy sources focused into/onto the precursor fluids, such as one or more focused spots or lines of laser light, focused electron beams, focused ion beams, or focused particle bombardment (e.g. from a particle accelerator); secondary heating means may also take the form of resistive heating of the precursor fluids (e.g., passing electrical current through a wire), inductive heating of the precursor fluids, or high pressure discharges through said precursor fluids. Any of these secondary heating means 40 can be used individually or in combination with one or more other secondary heating means 40.

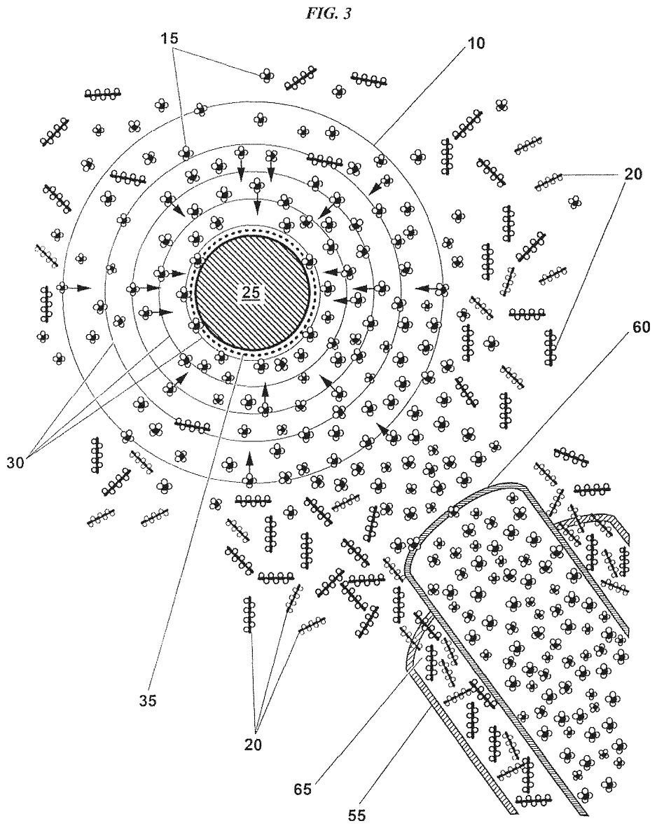

FIG. 3 depicts one embodiment of the invention where two highly disparate molar mass precursors are flowed coaxially through a coaxial tube 55, having a LMM precursor tube 60 and a HMM precursor tube 65, directing flow toward the reaction zone 35. In other embodiments, the LMM precursor 15 and HMM precursor 20 can be pre-mixed. This implementation can directly feed the center of the thermal diffusion region 10, increasing the growth rate of the fiber or fibrous material 25 by reducing the precursors' transport time through the fluid. Again, the LMM precursor 15 usually tends to concentrate at the region of greatest temperature surrounding the reaction zone 35. The HMM precursor 20 species tends to be displaced away from the reaction zone 35 at the outside of the thermal diffusion region 10, and as a result, tends to thermally insulate the reaction zone 35. Thus, the LMM precursor 15 is decomposed in the reaction zone 35 and deposits, resulting in fibrous material growth.

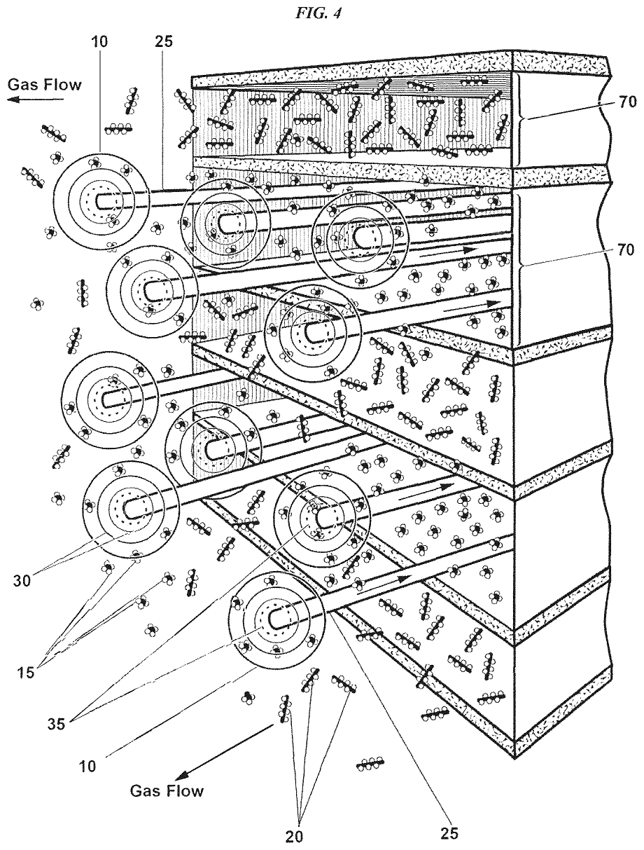

FIG. 4 shows another embodiment of the invention, where two highly disparate molar mass precursors are flowed in precursor planar flow sheets 70 toward the reaction zones 35 of an array of fiber(s) or fibrous material(s) 25. This implementation can also directly feed the center of the thermal diffusion regions 10 in the array, increasing the growth rate of the fiber(s) or fibrous material(s) 25 by reducing the precursor's transport time through the fluid. The fibers or fibrous materials 25 are drawn backward (as shown by the arrows) as the reaction zones 35 and thermal diffusion regions 10 remain substantially stationary in space. For practical considerations, this arrangement of stationary reaction zones and thermal diffusion regions is often preferred, but not required. Again, the LMM precursor 15 usually tends to concentrate at the regions of greatest temperature surrounding the reaction zones 35. The HMM precursor 20 species tends to be displaced away from the reaction zone 35 at the outside of the thermal diffusion regions 10, and as a result, tends to thermally insulate the array of reaction zones 35. Again, the LMM precursor 15 is decomposed in the reaction zone 35 and deposits, resulting in fibrous material growth.

As shown in FIG. 4, the planar sheets 70 may alternate between LMM precursor 15 and HMM precursor 20, where the LMM precursor 15 flows directly into the thermal diffusion region 10. Any number of fibers or fibrous materials 25 can be grown in this configuration. And any of the alternate primary heating means discussed above can be used, but are not shown in FIGS. 3 and 4.

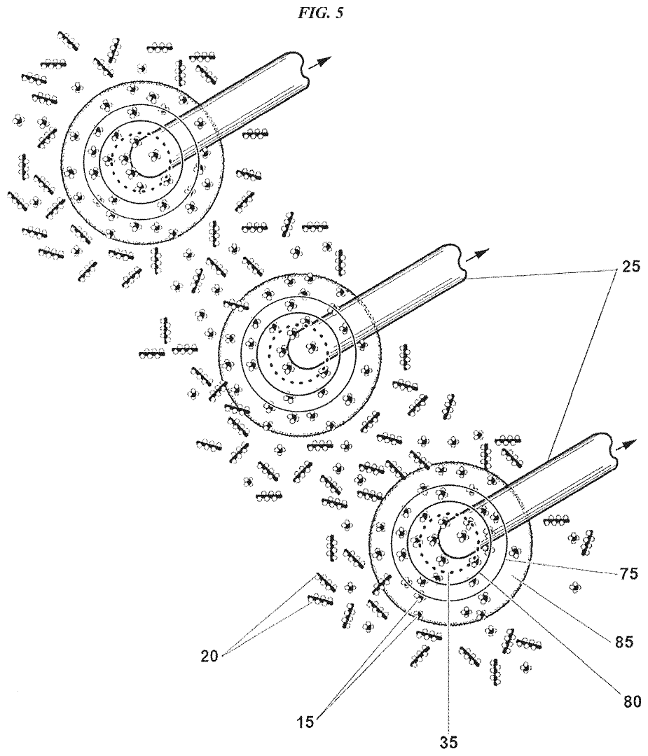

For example, FIG. 5 shows another embodiment of the invention having thermal diffusion regions that exist in a two-phase, gas+liquid system. In this embodiment, a gas bubble 75 is created. Within the gas bubble 75, there is an internal thermal diffusion region 80 and a reaction zone 35. Also, within the liquid there will be a second, external thermal diffusion region 85. Separation between the HMM and LMM precursors can occur in both regions 80, 85, and the properties of the precursors (including mass) determine the degree of separation in each. Again, the fiber(s) or fibrous material(s) 25 are drawn backwards (shown by the arrow) in this embodiment, while the gas bubbles 75, the thermal diffusion regions 80, 85, and the reaction zones 35 remain substantially stationary in space.

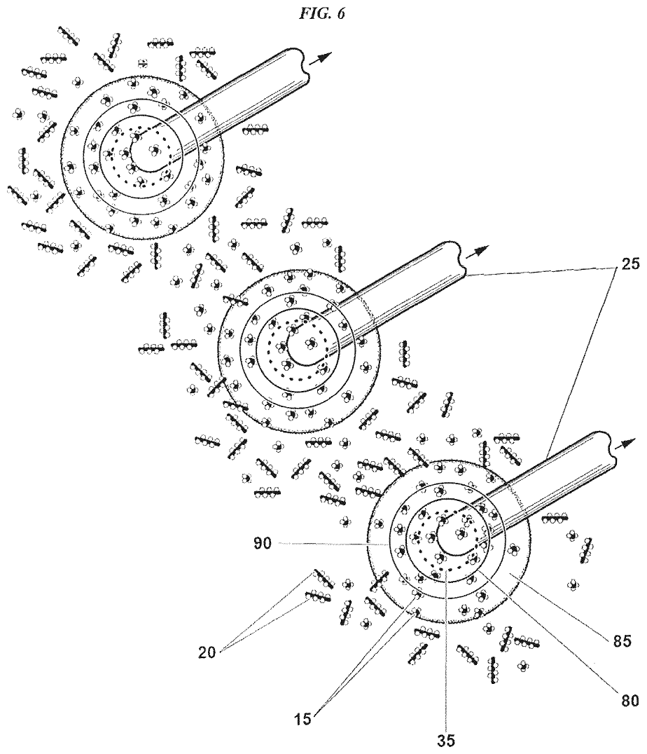

FIG. 6 shows another embodiment of the invention having two thermal diffusion regions 10 that exist in a “two-phase” system, where one fluid 90 (e.g. a critical/supercritical fluid), can be present around the reaction zone 35, and an internal thermal diffusion region 80 can exist within this fluid 90. Outside of the internal thermal diffusion region 80, another external thermal diffusion region 85 can exist within another fluid or solid phase. Separation can occur in both regions 80, 85, and the properties of the precursors (including mass) determine the degree of separation in each. This embodiment may be utilized, for example, when a highly pressurized liquid or solid precursor mix is heated by one or more primary heating means 40.

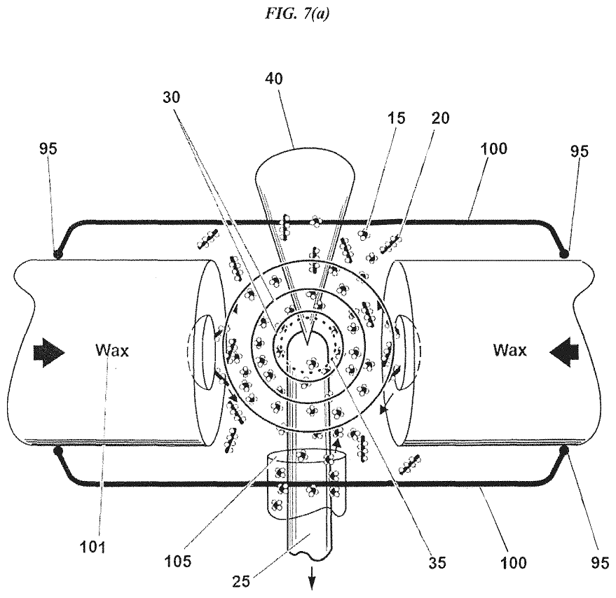

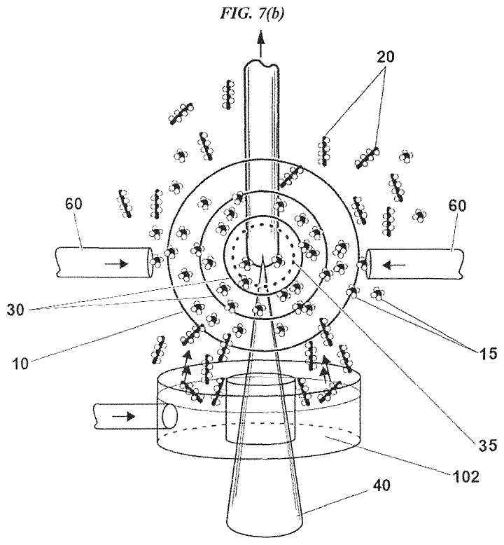

FIG. 7(a) shows one embodiment of the invention where a solid source (wax in FIG. 7(a)) of HMM precursor 20 is evaporated by one or more primary heating means 40 or secondary heating means 110 (not shown) near a gaseous thermal diffusion region 10. This solid source can be introduced at or near the thermal diffusion region 10 in numerous ways including extrusion through vacuum/pressure seals 95 in the vessel walls 100. Again, the reaction zone 35 and thermal diffusion region 10 remain stationary in this embodiment, while the fiber or fibrous material 25 is drawn backwards (as shown by the arrow). The LMM precursor 15 can be flowed separately through a nozzle 105 to the reaction zone 35, and can be placed in multiple possible orientations, including through a tube in the solid source of HMM precursor 20 (not shown). It is also possible to entrap the LMM precursor 15 within the HMM precursor 20 solid, and to release both at the thermal diffusion region 10.

FIG. 7(b) shows another embodiment of the invention using a liquid source of HMM precursor 102. The liquid source can be stationary or flowing below the thermal diffusion region 10, where the liquid evaporates to provide the HMM precursor 20. Also shown is a LMM precursor tube 60 for introducing the LMM precursor 15. It is also possible to dissolve or entrap the LMM precursor 15 within the HMM precursor 20 liquid, and to release both at the thermal diffusion region 10.

Importantly, in FIG. 7, the HMM and LMM precursors may “wick” from a precursor that is a liquid, critical/supercritical fluid, solid, semi-solid, soft plastic solid, glassy solid, or very viscous liquid—into the reaction zone(s) using a “wicking means,” such as: (1) wicking along fiber(s) or fibrous material(s) that are being grown, (2) wicking along a non-growing fiber(s) or fibrous material(s) to a growing fiber or fibrous material, or (3) along a secondary heating means, e.g. a coil around a growing fiber or fibrous material. Such precursors can be extruded/driven/flowed into the chamber (on-demand) through an orifice or tube to the locations of the wicking means. This can provide an additional means of controlling the growth rate of the fibrous materials by controlling the rate of wicking to the reaction zone(s).

In the embodiments shown in FIGS. 7(a) and (b), the primary heating means 40 is depicted as a focused laser beam. As discussed herein, other primary heating means 40 can be used, and secondary heating means 110 (not shown) can be employed to control the thermal diffusion region.

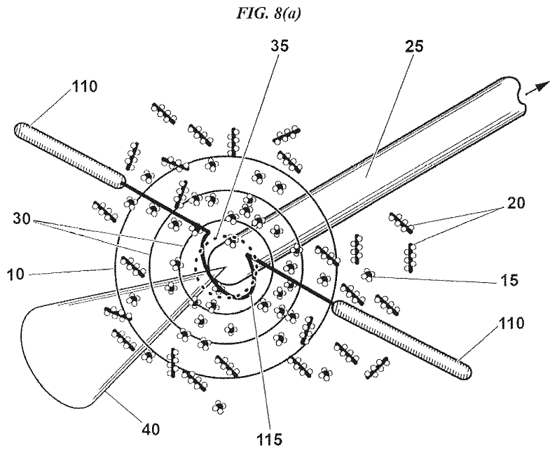

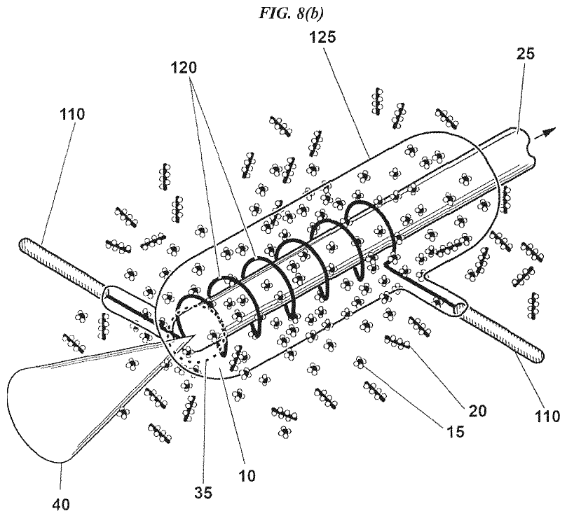

FIG. 8(a) shows another embodiment of the invention using a secondary heating means 110 (a resistive wire) to heat the thermal diffusion region 10 at the reaction zone 35 of the fiber or fibrous material 25. In this embodiment, the secondary heating means 110 in the thermal diffusion region 10 is a resistive wire preferably of fine diameter, and of resistance sufficient to provide a desired heating rate for the voltage applied. Outside of this region, it could be of larger diameter and/or conductivity to reduce heating elsewhere. In one embodiment, shown in FIG. 8(a), the secondary heating means 110 (wire) has a single partial loop 115. The secondary heating means 110 and single partial loop 115 use resistive heating to heat the fiber and surrounding gas to create and/or enhance a thermal diffusion region 10 and reaction zone 35 around the tip of the fiber or fibrous material 25. FIG. 8(a) also shows the use of a primary heating means 40, which in this embodiment, is a focused laser beam.

FIG. 8(b) shows another embodiment of the invention using a secondary heating means 110 comprised of a wire coil 120 surrounding a fiber or fibrous material 25. This allows the creation of an elongated thermal diffusion region 125. This wire coil 120 could also be considered a primary heating means, if it were to raise the temperature of the fiber or fibrous material and reaction zone through inductive heating.

As mentioned before, when a secondary heating means is used, in addition to influencing the thermal diffusion region, it can partially decompose the HMM precursor 20 or LMM precursor 15 near the reaction zone 35, thereby creating another set of precursor species of even lower molar mass (which we denote as a “derived precursor species”).

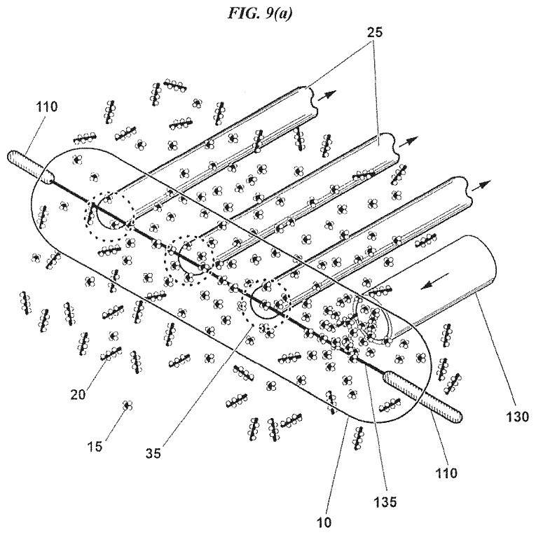

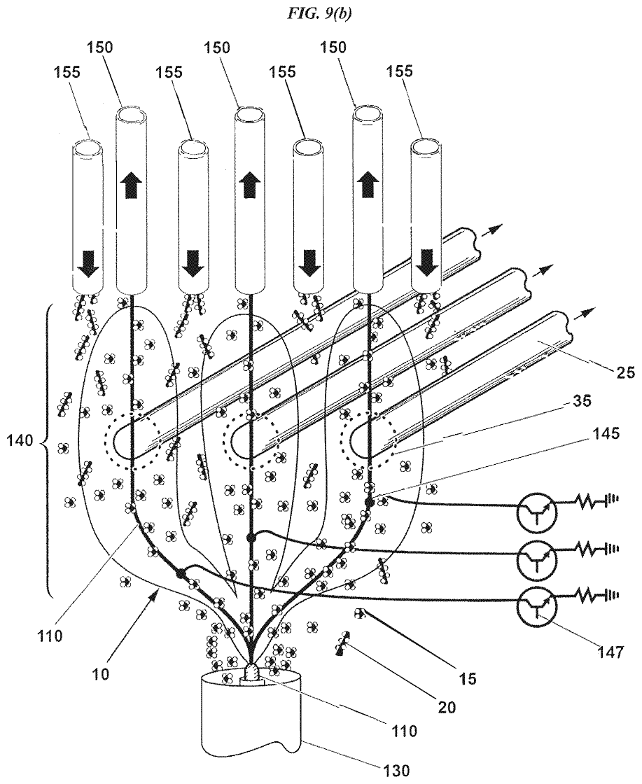

FIG. 9(a) shows another embodiment of the invention used to fabricate solid fiber(s) or fibrous material(s). Generally, at least one LMM precursor 15 species is introduced, or flowed into a vessel, in proximity to at least one secondary heating means 110 (e.g. the heated wire shown), and at least one HMM precursor 20 species is introduced into the vessel. As discussed above, the HMM precursor 20 preferably has a mass substantively greater than the LMM precursor 15 species, and preferably of thermal conductivity substantively lower than that of the LMM precursor 15 species. The HMM precursor 20 can be provided by any of the other methods discussed herein. In this implementation, the thinner, hot portion of the wire 135, creates an elongated thermal diffusion region 10; this elongated thermal diffusion region geometry provides a preferred conduit that follows the secondary heating means 110 (wire in this embodiment), along which the LMM precursor 15 will flow to reach reaction zones 35. The array of reaction zones 35 are created within the vessel by one or more primary heating means 40 (not shown for clarity), and decomposition of at least one of the precursor species occurs; this decomposition results in the growth of solid fiber(s) or fibrous material(s) 25 at each said reaction zone(s) 35. The solid fibers or fibrous material(s) 25 have a first end at the reaction zone(s) 35 and a second end that is drawn backward (shown by the arrow). The second end can be drawn backward by a spooling device/mandrel 50 (not shown) and may include a tensioner 45 (not shown). Preferably, the second end(s) are drawn at a rate to maintain the first end(s) within the reaction zone(s) 35.

In a related implementation to FIG. 9(a), at least one thermal diffusion region 10 is created or established at/near the reaction zone(s) to partially or wholly separate the LMM precursor 15 species from the HMM precursor 20 species using the thermal diffusion effect, thereby concentrating the LMM precursor 15 species at each reaction zone(s) 35. A secondary heating means 110 (wire in this embodiment) is passed or configured in proximity to the reaction zone(s) 35, to further concentrate the flow of LMM precursor 15 species along the heated wire(s) and into the reaction zone(s) 35 using the thermal diffusion effect, thereby creating a selective conduit to flow the LMM precursor 15 species to the reaction zone(s) 35. By concentrating the LMM precursor 15 species as described, it substantively enhances the growth of solid fiber(s) or fibrous material(s) 25, and the HMM precursor 20 species substantively decreases the flow of heat from said reaction zone(s) 35, relative to that which would occur using the LMM precursor 15 species alone.

FIG. 9(b) shows another embodiment and implementation, where one or more sources of LMM precursor 130 supply LLM precursor 15 to a manifold of thermal diffusion conduits 140, where the LLM precursor 15 branches and flows along individual thermal diffusion conduits, created by individual secondary heating means 110 (wires) that can be electrically-modulated via switches (represented by the transistor symbol). As the electrical current can be switched away from the reaction zones 35 to the transistors, the switch connections 145 acts as “thermal diffusive valves” that modulate the instantaneous flow of the LLM precursor 15 to (or away from) each fiber or fibrous material 25. In FIG. 9(b), the HMM precursor 20 is provided by a HMM precursor supply source 155, but the HMM precursor 20 can be provided by any of the other methods discussed herein. In addition, the byproducts of the reaction are also carried along the secondary heating means 110 (wire), and given the general flow direction, tend to be removed at separate outlet manifolds 150. In this way, the thermal diffusion regions 10 and secondary heating means 110 “conduits” can be used to remove byproducts that can otherwise affect the reaction. Thus, in some embodiments, byproduct species from the decomposition are flowed away from the reaction zone 35 along one or more of the secondary heating means 110, thereby removing the byproduct species from the reaction zone 35, and dispersing them into the reaction vessel, or allowing them to be removed from the reaction vessel altogether (for example, via an outlet manifold 150). Separate inlets are provided for the HMM precursor supply source 155, as shown.

Also remember that using the embodiment of FIG. 9(b), the electrical current in the wire can be controlled to modulate the concentration of LMM precursor 15 and HMM precursor 20 present at the reaction zone 35, thereby controlling the decomposition and growth of the solid fiber or fibrous material 25 independent of the primary heating means 40 (not shown for clarity). By modulating the concentration of the precursors, solid fibers or fibrous materials can be grown with desired geometries, diameters, microstructures, compositions, physical properties, chemical properties, coatings (including presence, absence, or thickness of the coating), and growth rates (collectively referred to herein as “fiber characteristics”).

In a similar embodiment to the invention of FIG. 9(a), each secondary heating means 110 (wire) may be comprised of two or more thin wire sections, with a thicker (less resistive) short section in-between. This in-between section may be heated by a laser beam (or other heating means) to modulate the flow of the LMM precursor 15 to the reaction zone 35, effectively creating a structure similar to a “thermal diffusion transistor.” In another implementation, one or more sections may have attached cooling fins that may be heated resistively and used to modulate the flow of the LMM precursor 15 to the reaction zone 35 (another form of a thermal diffusion switch/transistor). In another implementation, one or more of the secondary heating means 110 (wire) sections may also have attached dispersion wires that may be heated resistively to disperse the LMM precursor 15 species elsewhere and used to modulate the flow of LMM precursor 15 species in real-time to the reaction zone(s) 35 (i.e., the dispersion wires act as an inverse thermal diffusion valve). The heated wires may also be in the form of a microtube that is heated by passing hot fluid through the microtube.

In most embodiments, the invention incorporates feedback means to measure characteristics of the fibers or fibrous material(s) 25 being fabricated, and then use this feedback to control one or more aspects of the fabrication process and ultimately fiber characteristics/properties. Measurements of the geometry, microstructure, composition, and physical properties of the fibers or fibrous material(s) can be made as they are grown. This feedback can be used to control the primary heating means(s) 40 and/or secondary heating means 110. For example, in FIG. 9(b), the electrical current through the secondary heating means 110 (which form the conduits of manifold 140) can be controlled to alter the ongoing fabrication of the fibers or fibrous material(s) 25. This can be done independently, or at least partially independently, of any primary heating means 40 being used. For example, if the feedback means detects a composition of a fibrous material that results from a less-than-optimum LMM precursor concentration at the reaction zone 35, the current through the wire can be increased, thereby increasing the temperature of the wire, and flowing additional LMM precursor through the conduit to obtain the desired fibrous material composition.

The feedback means (not shown in FIG. 9(b) include electromagnetic sensing devices and can be of various types known to those of skill in the art. A non-exhaustive list of examples of feedback means include real-time FT IR spectroscopy, Raman spectroscopy, fluorescence spectroscopy, X-ray analysis, two and three color pyrometry measurements, and optical, UV, and IR imaging, narrow band detection of emission/absorption lines, reflectivity/absorption measurements, etc. Similarly, feedback means for the concentration/density of LMM precursors 15 and HMM precursors 20 species in the thermal diffusion regions 10 and/or reaction zones 35 can be obtained using real-time shadowgraphy, Schlieren techniques, and spectroscopy techniques. In other embodiments, the feedback means can be acoustic sensing devices. This is not intended as an exhaustive list. Various feedback means can be used individually or in combination.

Other devices and methodologies can also be used to obtain feedback of the process, and control the fabrication. In some embodiments, either together with one or more of the options discussed above, or by itself, the thermal diffusion regions 10 and/or the reaction zone 35 can be measured with real-time shadowgraphy or Schlieren imaging techniques to obtain feedback on the relative concentration/densities of the LMM precursors 15 species relative to the HMM precursor 20 species. Thus, in this embodiment, the feedback means is measuring the thermal diffusion region 10 and/or the reaction zone 35, rather than the fiber characteristics. This feedback can be used as input to control one or more aspects of the fabrication process, for example, modifying the primary heating means 40 or secondary heating means 110 to obtain solid fibrous materials at a desired rate with desired fiber characteristics.

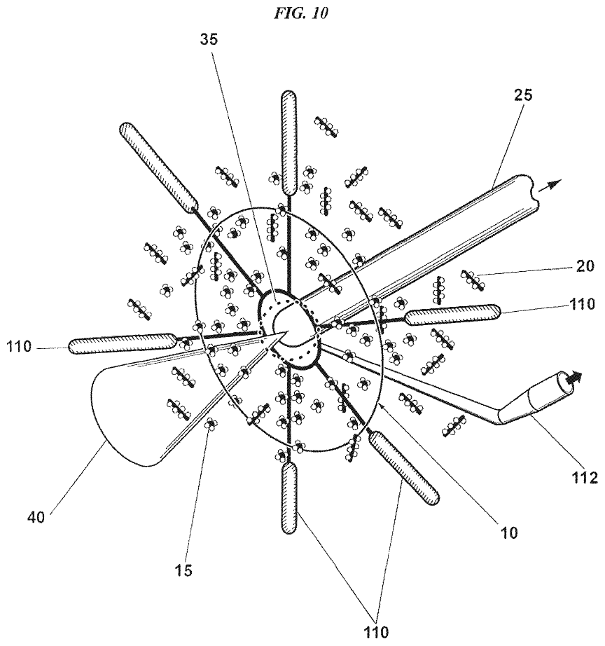

FIG. 10 shows another embodiment of the invention. In this embodiment, a series of secondary heating means 110 (in the form of wires) are connected to a current source (not shown) and converge on and surround the reaction zone 35 of fiber or fibrous material 25. The flow of current through any particular wire 110 can be regulated to control the heating rate of that wire. In one embodiment where the LMM precursor 15 and HMM precursor 20 are in a gas mixture, the concentration of the LMM precursor 15 can be varied by modulating the amount of current in the wires 110. When all the wires 110 are heated, the LMM precursor 15 is drawn out of the surrounding gas mixture and is concentrated at the reaction zone 35. When the wires are turned off, the concentration of LMM precursor 15 is diminished. The primary heating means 40 in this embodiment is a focused laser beam. The return conductor 112, provides a return path for the current from wires 110.

FIG. 11 shows a flow diagram of one embodiment of the invention with feedback means 156 which are used to control the growth of multiple fibrous materials, by modulating the reaction zones 35 (shown) and thermal diffusion regions 10 (not shown). In this particular implementation, a vision system is used as the feedback means 156, which can track the growth and characteristics of many fibrous materials at once. Based on the input from the vision system, a controller 160 determines what parameter changes in the fabrication process need to be made, if any, to achieve the desired fibrous material growth rates and properties; the controller 160 contains the necessary hardware and software to receive the vision system inputs and pass appropriate signals to a multi-output analog amplifier 165 and/or motor controller driver 170. Here, the analog amplifier 165 provides current to the secondary heating means 110 (which are in the form of wires). The current in the wires control the thermal diffusion region (not shown) and concentration of LMM precursor in reaction zones 35. The return path for the current in each wire is not shown. With input from controller 160, the motor controller driver 170 controls the spooling device/mandrel 50, and the winding rate of the fibrous material. In this way, controller 160 can modulate/control the fibrous material growth rate and properties, such as diameter, composition, microstructure, and bulk material properties—as well as process parameters such as precursor concentrations, flow rates, pressures, and induced temperatures. The controller 160 and its various configurations and interactions with the other elements used to control fibrous material growth and properties may be referred to herein as “controlling means.”

In one embodiment, the secondary heating means 110 is chosen from the group of: resistively heated wire(s), or focused infrared-, microwave-, millimeter-wave-, terahertz-, or radio-frequency electromagnetic radiation. If a resistively heated wire is used, in some embodiments, the heated wire(s) passes through, or encircles, the reaction zone(s) 35. In other embodiments, heated wires are interconnected to create at least one thermal diffusive valve. In some embodiments, the heated wire extends to the precursor inlet channel, creating a thermal diffusive conduit to the reaction zone 35 and thermal diffusion region 10, and/or the heated wire extends to the byproduct outlet channel thereby creating a thermal diffusive conduit (for example, see FIG. 9(b)). The same feedback means and control devices discussed above can be used to control the process (for example, the secondary heating means) to control the fiber characteristics of the fibers or fibrous materials 25 being fabricated.

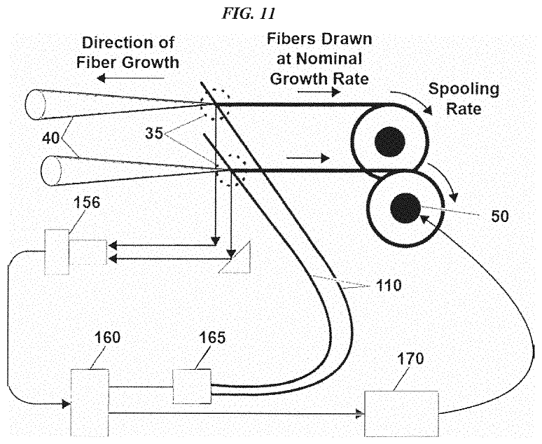

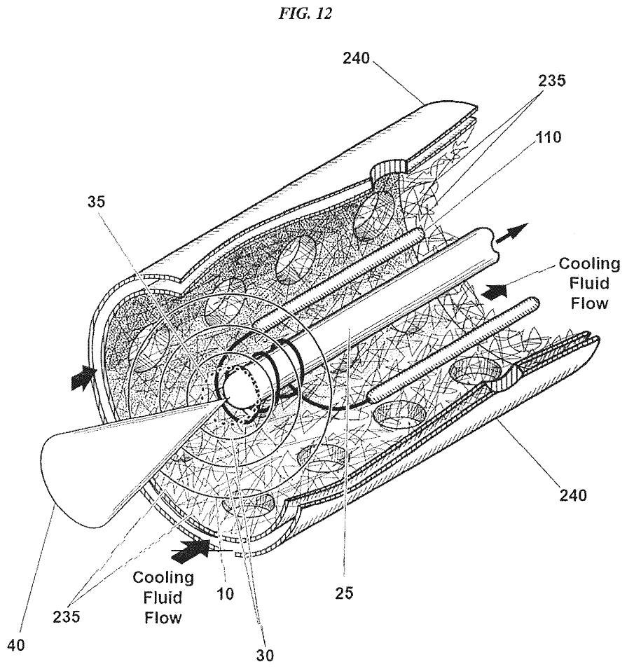

FIG. 12 shows one embodiment of this invention using a baffle. In this embodiment, the thermal diffusion region 10 can be protected by a wool-like webbing 235 and/or baffle 240 that prevents advection from overcoming the thermal diffusion region 10. The baffle 240 may be a solid structure, or can be a solid structure with holes or perforations. In the embodiments using a wool-like webbing 235 with a baffle 240 “conduit,” the wool-like webbing 235 can be on the outside or the inside of the baffle 240 “conduit”. A means for cooling the gas in the outer region of the thermal diffusion region 10, or outside of the thermal diffusion region 10, can also be used, including use of a heat sink, heat pipe, or actively cooled porous surface placed near/at the boundary of a thermal diffusion region 10. FIG. 12 shows a cooling fluid flow through a channel in the baffle 240 for cooling.

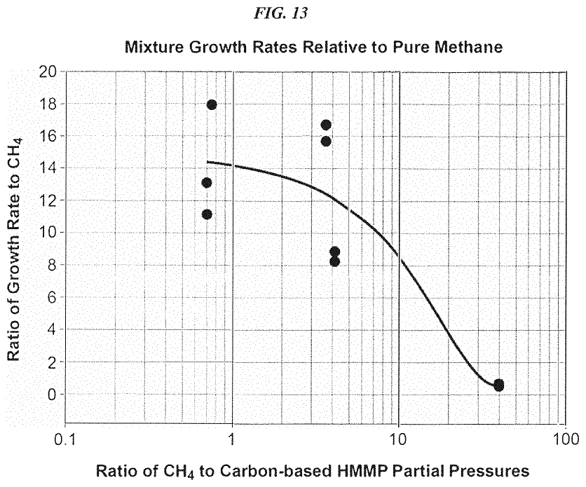

FIG. 13 is a graph showing how the use of HMM and LMM precursors can be used to advantage to obtain greater growth rates. We have normalized both axes to the growth rate and concentration of methane alone. As the ratio of the HMM hydrocarbon precursor to methane goes to zero, we approach the growth rate of methane alone. However, for reasonable LMM/HMM mixtures (1:1-1:5), there is an enhancement in the growth rate over that of methane alone—of almost one order of magnitude.

While the disclosure above primarily discusses decomposition and disassociation of the precursors using various heating means, it should be recognized that other methods can also be used. For example, the precursors can be decomposed chemically, using X-rays, gamma rays, neutron beams, or other systems and methodologies. Additionally, while many embodiments discuss drawing a fibrous material backward during fabrication, and largely keeping the reaction zone stationary, it should be recognized that the fibrous material could remain stationary, and the reaction zone 35 and/or thermal diffusion region 10 be moved. For example, the placement of the primary heating means(s) 40 can be moved. In one embodiment using a stationary fibrous material, if a laser beam is used as a primary heating means 40, the direction/orientation of the laser beam can be changed, the laser can be placed on a moveable, translatable mount, or various optics and lenses can be used to alter the focus of the laser. Similarly, if heated wires are used as the primary heating means 40, the wires can be moveable and translatable such that the thermal diffusion region 10 and/or reaction zone 35 can be moved.

Additionally, while the disclosure primarily relates to and utilizes LMM precursors and HMM precursors having highly disparate molar masses, the modulation of the thermal diffusion region 10 and/or reaction zone 35, can still be utilized, and highly beneficial, for many different types of precursors, even when their respective molar masses are not substantively different.

### Scavenging By-Product Species Through Control of the Thermal Diffusion Region

This invention also addresses methods of overcoming the thermal diffusion growth suppression (TDGS) effect, mentioned previously. Often during rapid fibrous material growth a considerable amount of byproducts are generated during decomposition—and these by-products may accumulate at the fibrous material tip and center of the reaction zone(s)—and the precursor is displaced from the center of the reaction zone(s). In this case, it is even possible for the newly-deposited fibrous material to be etched by some of the by-products along the center of the fibrous material axis. Consider one example chemical reaction, using methane as an LMM precursor for carbon fiber deposition and SF6 as an HMM precursor:

3CH_{4(ad)}+2SF_{6(ad)}→3C₍ₛ₎+2S_{(ad)}+12H_{(ad)}+12F_{(ad)}→3C₍ₛ₎+2S_{(s,g)}+12HF_{(g)}

(Note: the intermediate state shown above is for illustrative purposes only. The actual reaction may be much more complex with more than one possible pathway.) In this reaction, the carbon fibers grew very rapidly, and then suddenly slowed, and completely etched away. The initial growth rates were on the order of 3-4 mm/s, which (for a given CH₄ partial pressure) is about 1-2 orders of magnitude greater than that from pure CH₄. During initial growth, byproducts were building up around the reaction zone that eventually caused the fibrous material growth rate to slow; when the concentration built up sufficiently, the reaction reverses, and the fibrous materials etch away at mm/s rates. Note that temperature of the carbon fibers were essentially constant throughout. However, if the reaction was stopped momentarily during the initial stages, the growth would recommence rapidly again soon thereafter; this means the by-products/etchants were dispersed when the growth stopped because the thermal diffusion effect disappeared momentarily. Free hydrogen, fluorine, and hydrofluoric acid at the fiber tip were the likely etchants that built up and needed to be removed.

An important concept comes from this example: the ability to “scavenge by-products.” One reason that the reaction proceeded rapidly at first is because the hydrogen (that normally dampens the growth rate at the fiber tip) is scavenged by the free fluorine forming HF. Hydrofluoric acid is much more massive than hydrogen and slightly more massive than CH₄. Thus, when it forms, the thermal diffusion effect drives the HF away from the hottest portion of the reaction zone, at least until it reaches a large concentration. This temporarily took away the hydrogen TDGS at the fiber tip and allowed the fibrous material to grow more rapidly than it ordinarily would. The reaction of the CH₄ with SF₆ also changes the kinetics of the reaction, but since the reaction is mass transport limited under these conditions, the rate change is coming from the transport of the precursors and byproducts, not the change in reaction rate.

Thus, in this and similar situations, one can use control of the thermal diffusion effect advantageously in several ways. First, when the TDGS effect occurs, one can grow until the fibrous material begins to slow, then stop momentarily, to disperse the byproducts, and begin again. The problem with this approach is that the fibrous material properties may change at each momentary stop; however, this technique may be useful for chopped fiber production. Second, one can use a pulsed or modulated laser to allow dispersion between pulses/waves, without completely stopping the reaction (this may provide better continuous mechanical properties). Third, one can use a pulsed or continuous flow of gas across the reaction zone to forcibly remove the byproducts. Fourth, one can use a secondary heating means, e.g. a wire, to move byproducts away from the growth zone. Fifth, one can use a “scavenger” that will result in a more massive byproduct (preferably more massive than the precursor), and the undesired low-molar mass byproducts will be displaced farther from the reaction zone. This scavenges the low-molar mass byproduct species by turning them into a higher-mass scavenged byproduct (SBP) species.

While the scavenging example above is for carbon and carbon-doped fibrous materials, the general method of scavenging described to produce a SBP species, can readily be applied to other material systems, including those other material systems described in this disclosure.

In one particular embodiment of this invention, a method of growing solid fiber(s) or fibrous material(s) is disclosed, comprising (a) introducing at least one low-molar mass (LMM) precursor species into a vessel; (b) introducing at least one high-molar mass (HMM) precursor species into said vessel, of mass substantively greater than the LMM precursor species (preferably at least 1.5 times greater, and more preferably 3 or more times greater), and of thermal conductivity substantively lower than that of the LMM precursor species; (c) creating an array of reaction zone(s) within a vessel by a primary heating means, wherein decomposition of at least one LMM precursor species occurs, yielding at least one LMM byproduct species, and wherein decomposition of at least one HMM precursor species occurs, yielding at least one HMM byproduct species; (d) said decomposition resulting in the growth of solid fiber(s) or fibrous material(s) at each said reaction zone(s); said solid fiber(s) or fibrous material(s) being comprised of at least one element from said precursor species; (e) said at least one LMM byproduct species reacting with said at least one HMM byproduct species, yielding an scavenged byproduct (SBP) species of molar mass greater than said LMM precursor species; (f) establishing thermal diffusive regions (TDRs) at/near said reaction zone(s) to partially or wholly separate said LMM precursor species from the HMM precursor species using the thermal diffusion (Soret) effect; (g) said TDRs also partially- or wholly-separating said LMM precursor species from said SBP species, displacing said SBP species away from said reaction zone(s), thereby removing (i.e. scavenging) LMM byproduct species from said reaction zone(s), thereby enhancing said growth of solid fiber(s) or fibrous material(s); (h) said solid fiber(s) or fibrous material(s) have a first end at said reaction zone(s) and a second end that is drawn backward through a tensioning and spooling means, at a rate to maintain the first end within (or near) said reaction zone(s). A secondary heating means can be provided and can include any of the embodiments and configurations discussed above, and may be used to modulate the concentration and flow of precursor and SBP species and control the reaction zone(s) and thermal diffusion region(s) discussed herein. Feedback and control means may also be utilized. In some embodiments, the secondary heating means (e.g., heated wires), pass near said reaction zone(s) to further draw SBP species away from said reaction zone(s).

### Functionally-Shaped and Engineered Short Fiber and Microstructures

As noted above, for brevity, much of the disclosure contained in U.S. application Ser. No. 14/827,752 is not repeated here, but can be utilized in connection with the present disclosure, including but not limited to those aspects related to functionally-shaped and engineered short fiber and microstructure materials.

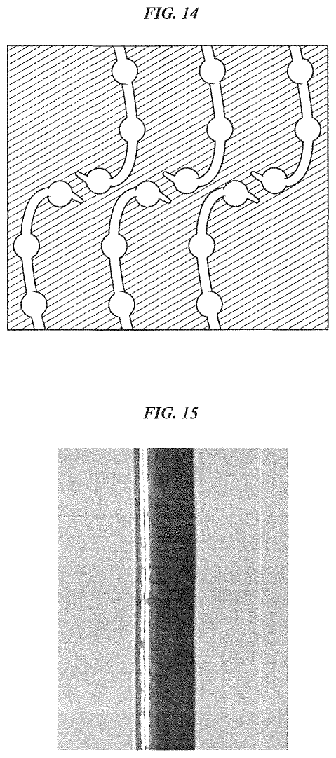

For example, refractory fiber(s) or fibrous material(s) can be grown in short or long filaments to predetermined lengths, and their diameters can be controlled to specific diameters—or varied intentionally. Complex shapes can be created by changing the intensity of the primary and/or secondary heating means, even as it is reoriented. For example, a complex curved fibrous material can be created with periodic undulations along its length (see FIG. 14). And it is possible to change the cross-sectional shape, even as cross-sectional size and orientation of the fiber is changed.

The ability to modulate the cross sectional diameter/shapes of refractory fibrous materials over a variety of length scales is especially important for improving ultra-high temperature carbon-matrix, metal-matrix and ceramic-matrix composites. By modulating the diameter, one can create “dog-bone” and “bed-post-like” fibrous material(s) that will resist pull-out from the matrix. And the ability to weave, braid, and interconnect refractory multiple fibrous materials also allows for novel reinforcement of ultra-high temperature composite materials, so that fibrous materials will not slip relative to each other.

Another aspect of this invention is that UHTM fibrous materials can be grown as arrays, tows, and near-net shapes in particular orientations, so that refractory composites can be reinforced in specific directions. This is especially important for applications such as turbine engine blades, where temperatures, shear forces, and centrifugal forces can be extreme. As a non-limiting example, a silicon carbon nitride fiber fibrous reinforcing material can be grown as a near-net shape of a turbine blade with more strands along the axial direction of a turbine blade than other directions for most of its length, but with more stands at its base in other directions to create “filets” where the blade attaches to its base.

Another aspect of this invention is that it can inherently provide local sub-100 nanometer smoothness in the surfaces that are grown, allowing for improved bonding at the fiber-matrix interface (e.g. through Van Der Waals or Covalent bonding) which is important for many carbon-matrix, metal-matrix and ceramic matrix composites. This can be improved to even greater precision through feedback control of the primary and/or secondary heating means and other process parameters during the growth process as described above. The carbon fiber shown in FIG. 15 is an example of a fibrous material grown with sub-100 nanometer local surface smoothness. Because the fibrous materials are not pulled through any mechanical spinning or drawing processes, they exhibit very few (if any) voids/cracks, and the material can be grown as a fully dense material. In addition, the material microstructure can be designed to be amorphous or glassy, which will give strong fibrous materials that have more uniform properties. Alternatively, in many instances, the material microstructure can also be that of single-crystal fibrous materials/whiskers, which may have much greater strength than polycrystalline forms of the same material.

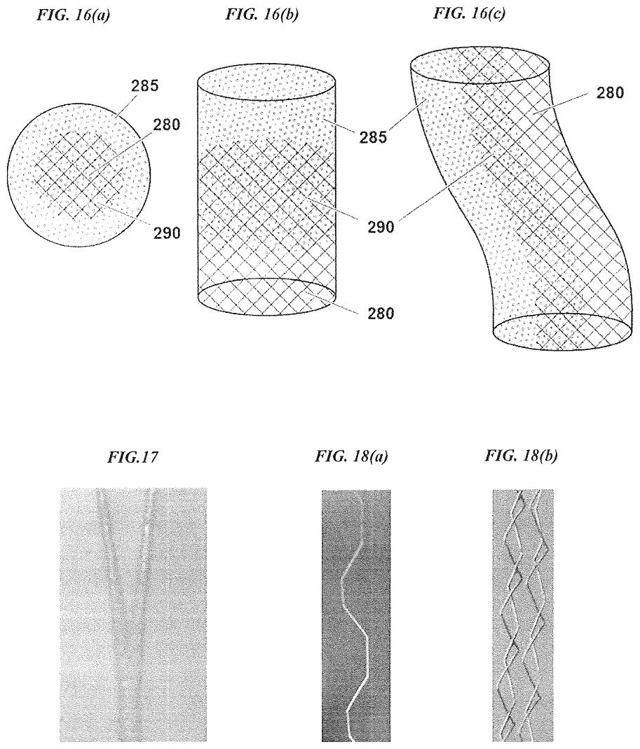

Another aspect of the invention is that multiple materials can be grown simultaneously to create a functionally-graded fibrous material. For instance, where two materials are deposited at the same time under a Gaussian laser focus, with different threshold deposition temperature and kinetics, one material will naturally be more highly concentrated in the core of the fibrous material, while the other tends to grow preferentially toward the outside of the fibrous material. However, rather than having a distinct step transition from one material to another, as would be present in a coating for example, they can be blended together with a gradual transition from core to outer material. This can create a stronger transition from core to outer material that will not separate. This permits a very strong material that might otherwise react or degrade in contact with the matrix material to be permanently protected by an exterior material that contacts the matrix material. This can potentially improve bonding between fibrous material and matrix materials, allow for flexible transitions between fibrous material and matrix, and prevent undesirable alloying or chemical reactions. There are many possible implementations of this multiple material approach, and the fibrous materials can be functionally graded radially and axially. The method for applying the precursors can also vary. For example, they can be flowed pre-mixed or separately to create anisotropic variations in composition (see FIG. 16). FIG. 16(a) depicts a radial blend of the deposited materials, shown as a cross section of a fiber or fibrous material. In this embodiment, a first material 280 is concentrated at the fiber core or core of the fibrous material, while a second material 285 is concentrated outside of the core. In most cases, there is a gradual transition portion 290, such that as you move away from the core, the deposited material transitions from the first material 280 to the second material 285. Additional materials could also be deposited in this fashion having a radial blend of multiple materials.

Such radial variations in composition are especially important for refractory fibers or fibrous materials, where multiple material properties are desired, such as strength and oxidation resistance. As a non-limiting example, consider a UHTM fibrous material that has a core of boron carbide, which possesses a tensile strength of 22 kpsi, and a density of 2.5 g/cm³, but oxidizes at 600-900° C.), which transitions radially to silicon carbide on its exposed surface (which has a tensile strength of 15 kpsi, and density of 3.2 g/cm³, but oxidizes at 1100-1300° C.). The core provides a significant strength to mass advantage, while the silicon carbide on the surface provides greatly improved oxidation resistance. And through use of the thermal diffusion region, and HMM and LMM precursors, we can better control this radial material blend.

FIG. 16(b) depicts an axial blend of the deposited materials. In this embodiment, a first material 280 is deposited as the fibrous material. The fibrous material then has a transition portion 290, where the fibrous material transitions to a second material 285. Again, additional materials could be deposited. FIG. 16(c) depicts an anisotrophic blend of the deposited materials. In this embodiment, a first material 280 is deposited in one portion of the cross section of the fibrous material, while a second material 285 is deposited on a separate portion of the cross section of the fibrous material, with a transition portion 290 separating the two materials. It should be noted that the transition portion 290 is optional, and may not be needed depending on the desired fibrous material characteristics, precursors used, heating conditions, etc.

Importantly, fibrous materials can also be branched to create additional resistance to fiber pull-out. Fibers and fibrous materials can form networks of connected strands, an example of which is shown in FIG. 17. The branched fiber shown in FIG. 17 was created using two primary heating means (laser beams) overlapping, and then moving them apart during growth to separate the reaction (or growth) zone into two reaction zones. An example of zigzag fibers grown is shown in FIG. 18.

Individual fibrous materials made in accordance with this disclosure can range in diameter from a few tenths of a micron to several thousand microns. And fibrous materials can be grown to very long aspect ratios—and even as continuous filaments.

### Recording Information on Modulated Fibers, Microstructures, and Textiles—and Device for Reading the Same

Again, as noted above, for brevity, much of the disclosure contained in U.S. application Ser. No. 14/827,752 is not repeated here, but can be utilized in connection with the present disclosure, including but not limited to those aspects related to recording information on modulated fibers or fibrous materials, microstructures, and textiles and device for reading same.

Especially important for recording information in an archival manner is the production of refractory fiber(s), microstructures, and textiles that can withstand oxidation and weathering. Many of the materials discussed herein would be advantageous for such application, depending on the environment. As two non-exclusive examples, fibers of silicon nitride are oxidation resistant to temperatures of up to 1300° C., and could easily be doped or have modified geometries to record information—and could withstand conditions commonly present in house fires (which average 590° C.). Alternatively, aluminum oxide fibers could be used for storing information, and withstand temperatures in an oxidizing environment of up to 2000° C. And where oxygen is not present, information could be stored in Ta—Hf—C materials at temperatures exceeding 3800 K.

As another non-limiting example, fibrous materials can be additively manufactured or grown into compressed fibrous material, similar to paper, where the text is “written” in a refractory fibrous material that appears black (e.g. silicon boride) while the remainder of the paper is written from silicon carbide and appears white. Color versions could also be made. This would be a readable paper, where the text is written not only on the surface of the paper, but also into the paper, so that it is scratch resistant, oxidation resistant, and temperature resistant—and would remain in an archival state indefinitely. Imagine a bible that withstands 100,000 years of weathering, and can be exposed to water. The modulated shapes/surfaces of the written fibrous materials can also contribute to the color, texture, and contrast visible in such papers.

### Ultra-High Temperature Doped-Carbon and Carbon-Alloy Fibrous Materials

Some aspects of this invention provide a novel type of doped-carbon fibrous material, carbon-alloy fibrous materials, and carbon-mixture fibrous materials, a method of fabricating same, as well as a method of synthesizing many fibers simultaneously and fibrous forms of this material.

The novel materials associated with this aspect of the invention are doped carbon fibrous materials, and carbon-alloy fibrous materials, with various disordered morphologies, including: glassy, vitreous, amorphous, quasi-crystalline, nanocrystalline, diamond-like carbon, tetrahedrally-bonded amorphous carbon (ta-C), and turbostratically-disordered forms of carbon. Other morphologies include pyrolytic graphite, graphite, graphite aligned parallel to the fiber axis, graphene, graphene aligned parallel to the fiber axis, carbon nanotubes, carbon nanotubes aligned parallel to the fiber axis, fullerenes, carbon onions, diamond, lonsdaleite, and carbyne. In addition, these novel materials can also be doped with at least one element or compound that provides an improvement in properties of the material, or acts as a grain-refining or nucleation-aiding agent.

The invention also discloses the simultaneous introduction of multiple dopants, with varying atomic sizes. In this way, one can more easily create glassy carbon fibrous materials (and glassy carbon alloy fibrous materials) with various glass-transition temperatures and ranges of operation. It is also possible to create high-temperature refractory forms of glassy carbon, with transition temperatures greater than 1,000° C.

In one of its simplest forms, the method of this invention uses one low molar mass (LMM) precursor, and one high molar mass (HMM) precursor. As non-limiting examples, the LMM can be: methane, CH₄, or propyne, C₃H₄, and the high molar mass (HMM) precursor can be n-icosane, C₂₀H₄₂, or n-tetracontane, C₄₀H₈₂. It can also employ massive inert or reactive gases (e.g. xenon, or iodine) that are not intended to materially participate in the reaction. Preferably, at least one of the LMM or HMM precursor species is carbon-bearing (CB), e.g. carbon fluoride, CF₄, or adamantine, C₁₀H₁₆; and at least one of the LMM or HMM precursor species is dopant-bearing (DB), e.g. boron triiodide, BI₃ for boron doping, or silicon bromide, SiBr₄, for silicon doping. A precursor can also be carbon-bearing and/or dopant bearing. A precursor may also be multiple dopant bearing, e.g. borazine, B₃H₆N3 for boron and nitrogen doping.

In certain embodiments, the present invention is the first to actively control one or more thermal diffusion regions (or “TDRs”) in order to control the growth and properties of carbon and carbon alloy fibrous materials—as well as the concentration of dopants/alloys across the carbon fiber(s) or fibrous material(s). Note that modulating the TDR changes the background temperature of the gases, which can also influence the presence of intermediate species in the fluid. It also allows for continuous or periodic removal of byproducts that can otherwise build up at the reaction zones.

A wide variety of different LMM precursors and HMM precursors can be employed in combination in order to obtain the desired TDR and controlling effects for carbon fiber or fibrous material and carbon-alloy fiber or fibrous material. Some examples of LMM gases are discussed further herein. For example, for carbon deposition from an LMM precursor, hydrocarbons could be used with carbon chain lengths up to C=5, including the alkanes, alkenes, and alkynes, and small cyclic hydrocarbons, e.g. cyclopentane. For HMM gases, precursors such as hydrocarbons with carbon chain lengths greater than C=5, including the alkanes, alkenes, and alkynes, and branched hydrocarbons, aromatic/cyclic hydrocarbons (e.g. benzene toluene or naphthalene), halogenated hydrocarbons (e.g. tetraiodo methane, or perfluorohexane (C₆F₁₄)), and heavier hydrocarbons, e.g. waxes and oils can be used. This list is not intended to be exhaustive, and it is only for explanatory purposes. For instance, there are hundreds of possible hydrocarbon and wax combinations. It is the substantive difference in molar mass (as well as diffusivity) that drives the feasibility of each combination.

This invention also address thermal diffusion growth suppression (TDGS), which can be particularly problematic during the growth of carbon fibers or fibrous materials. Often during rapid fibrous material growth from hydrocarbons, a considerable amount of molecular and atomic hydrogen is generated during decomposition—and this hydrogen may accumulate at the fiber tip and center of the reaction zone(s), and the hydrocarbon precursor is displaced from the center of the reaction zone(s). In this case, it is even possible for the newly-deposited carbon to be etched in the center of the fibrous material by atomic hydrogen. Through the use of scavenging byproducts into SBP species, as described above, they hydrogen by-product can be removed, and the TDGS effect can be minimized.

One particularly useful (and simple) implementation of the method of scavenging byproduct species during carbon fiber or fibrous material growth, uses the gas mixture described previously, with CH₄ as the LMM precursor and CBr_{4(g)} as an HMM precursor. In this case, the following high-temperature reaction can be used to grow carbon fibers or fibrous materials:

CH_{4(g)}+CBr_{4(g)}→2C₍ₛ₎+4HBr_{(g)}, [Reaction A]

As the HBr byproduct is significantly more massive than the CH₄, it is an SBP species and should be dispersed farther away by the thermal diffusion effect than the LMM precursor. Addition of an appropriately designed secondary heating means can help to further remove this SBP species away from the growth zone.

Now, we should note that the CBr₄ molecule is often synthesized at low temperatures by the following reaction (sometimes using a catalyst):

CH_{4(g)}+4HBr_{(g)}→CBr_{4(g)}+4H₂ [Reaction B]

Thus, at the fiber tip, in one possible embodiment, Reaction A is run at high induced temperatures to produce carbon, then the HBr is dispersed into the remainder of the chamber (or to another location along a wire), and then Reaction B can be run at low temperatures, to cycle the bromine back to the CBr₄ precursor. Thus one only need to add CBr₄ once to the chamber, which is an expensive precursor, but one can continuously add CH₄ (e.g. in the form of natural gas), and energy through the primary and secondary heating means. As the bromine is continuously recycled in the chamber, there is little or no waste product from the system.

Various carbon fibers or fibrous materials and carbon-alloy fibers or fibrous materials can be manufactured using the systems and methods described herein. Thus, in one embodiment, solid doped fibrous materials can be manufactured wherein the solid doped/alloyed fibrous material is comprised of at least 55 at. % carbon, less than 40 at. % hydrogen, less than 45 at. % dopant/alloy element(s). In some embodiments, the solid doped fibrous material possesses an aspect-ratio (of length to cross-sectional width) greater than 3:1; and exhibits (1) amorphous, glassy, vitreous, random non-crystalline, or quasi-crystalline (“RNQ”) morphologies, or (2) nanocrystalline morphologies with grain sizes smaller than 100 nm, or (3) crystalline ultra fine-grained morphologies; and wherein the solid doped fibrous materials are grown predominantly through a heterogeneous reaction of gaseous, liquid, critical or supercritical fluid precursors in a reaction zone.

In various different embodiments, the solid doped carbon fiber(s) or fibrous materials can have (1) morphologies that possess diamond-like carbon, hydrogenated diamond-like carbon, or tetrahedrally-bonded amorphous carbon, (2) morphologies that are a single-phase and isotropic across the fibrous material, and (4) morphologies containing amorphous diamond with less than 5 at. % hydrogen.

Various dopant/alloy elements can be used, depending on the characteristics desired, but can include at least one of the following elements: Li, B, Mg, Al, Si, S, Ti, V, Cr, Mn, Fe, Co, Ni, Cu, Zn, Ga, Ge, Y, Zr, Nb, Mo, Tu, Rh, Pd, Ag, Cd, In, Sn, I, La, Ce, Pr, Nd, Sm, Eu, Gd, Ho, Er, Yb, Hf, Ta, W, Re, Os, Ir, Pt, Au, Bi, Th, U, Np, Pu, Am, Cm, and Cf In other embodiments, the dopant element can include at least one of the following elements: B, N, O, Si, S, F, Br, Cl, and I; as well as at least one of the following elements: Li, B, Mg, Al, Si, S, Ti, V, Cr, Mn, Fe, Co, Ni, Cu, Zn, Ga, Ge, Y, Zr, Nb, Mo, Tu, Rh, Pd, Ag, Cd, In, Sn, I, La, Ce, Pr, Nd, Sm, Eu, Gd, Ho, Er, Yb, Hf, Ta, W, Re, Os, Ir, Pt, Au, Bi, Th, U, Np, Pu, Am, Cm, and Cf. In other embodiment, a first dopant element and a second dopant element can be used from the foregoing lists.

In other embodiments, the dopant/alloy element(s) include at least two elements with substantively disparate atomic sizes, relative to each other, and relative to carbon, to aid in forming a glassy doped carbon material. By “substantive disparate atomic sizes,” we mean at least a 5% difference from that of the dominant element and from each other. For example, the applicant has grown B—C—N fibers or fibrous material where the boron is larger in radius, and the nitrogen is smaller in radius that the dominant carbon species, which has aided in forming glassy and ultra-fine-grained morphologies.

In some embodiments, the dopant/alloy elements are distributed isotropically throughout the cross-section of said solid doped fibrous material. In some embodiments, the dopant element(s) are intentionally distributed isotropically about the central axis of said solid doped fibrous material (in the azimuthal direction), but with specific radial concentration profiles from said axis to the surface of said solid doped fibrous material (i.e. in the radial direction).

In one embodiment for fabricating a solid doped/alloyed carbon fiber or fibrous material, the solid doped/alloyed fibrous materials are composed of at least 55 at. % carbon, and at most 40 at. % hydrogen, and at most 45 at. % dopant element(s). In one embodiment, the method comprises: (a) flowing at least two precursor species into a vessel in proximity to at least one secondary heating means (e.g. heated wires(s)), wherein at least one said precursor species is a carbon-bearing (CB) precursor species, and at least one said precursor species is a dopant-bearing (DB) precursor species; (b) wherein at least one said precursor species is a low molar mass (LMM) species; (c) wherein at least one said precursor species is a high molar mass (HMM) species, having a molar mass substantively greater than the LMM species, and of thermal conductivity substantively lower than that of said LMM species; (d) creating an array of reaction zone(s) within said vessel, wherein decomposition of at least one CB precursor species and at least one DB precursor species occurs; said array of reaction zone(s) being created by a primary heating means; (e) said decomposition resulting in the growth of solid doped carbon fiber(s) or fibrous material(s) at each said reaction zone(s); (f) said solid doped carbon fibers or fibrous material(s) having a 1st end at said reaction zone(s) and a 2nd end that is drawn backward through a tensioning and spooling means, at a rate to maintain the 1st end within said reaction zone(s); (g) at least one secondary heating means (e.g. heated wire(s)) being directed to/across said reaction zone(s); (h) establishing at least one thermal diffusion region (TDR), at least partially by means of said secondary heating means (e.g. heated wire(s)), to partially- or wholly-separate the LMM species from the HMM species using the thermal diffusion/Soret effect, thereby concentrating the LMM species at said reaction zone(s) and along said secondary heating means (e.g. heated wire(s)), and thereby (optionally) creating a selective conduit to flow the LMM species to said reaction zone(s); (i) said concentrating of LMM species, (optionally) substantively enhancing said growth of said solid doped carbon fiber(s) or fibrous material(s), and (j) said HMM species (optionally) decreasing the flow of heat from said reaction zone(s), relative to that which would occur using only the LMM species alone. Note that some aspects in this particular method are optional.

Primary heating means can include any single or combination of the heating means discussed herein, and the precursors can be flowed in any of the configurations discussed above. Any of the pressure control means can also be used. The precursors can also be in the various forms discussed above (e.g., all gaseous, some gaseous and some in liquid state, etc.).

In various embodiments, the secondary heating means can be used to partially decompose the CB precursor species and/or DB precursor species near the reaction zone(s), thereby creating another set of intermediate precursor species of lower molar mass. In some embodiments, an intermediate set of molar mass precursor species are introduced (a) to further separate the LMM species and HMM species; and/or (b) to react with and break down at least one of said (CB) precursor species and/or (DB) precursor species.

In some embodiments, at least one HMM species can be inert (e.g. argon, krypton, and xenon, or a xenon compound, e.g. xenon hexafluoride) and does not materially decompose at said reaction zone(s). In some embodiments, at least one of the (CB) precursor species and/or (DB) precursor species reacts with at least one HMM species, causing it to deposit, or partially-decompose yielding smaller precursor species that will be concentrated at said reaction zone(s). In some embodiments, the LMM species act as catalysts that decompose the HMM species to smaller precursor species that will be concentrated at said reaction zone(s). In some embodiments the HMM species physically or chemically inhibits the formation of clusters and particulates near said reaction zone(s).

In some embodiments, the LMM species enter the chamber near a secondary heating means (e.g. heated wire(s)), and flow along said conduits to said reaction zone(s). In some embodiments, the LMM species are concentrated by at least two secondary heating means (e.g. heated wire(s)); the secondary heating means (e.g. heated wire(s)) extending into the open spaces of said vessel, to draw LMM species from said open spaces, and allow flow of said LMM species along said conduits to said reaction zone(s).

In some embodiments, the byproduct species from the decomposition of a CB precursor species and/or DB precursor species are flowed away from said reaction zone(s) along a conduit; said conduit (optionally) extending to an exit point of said vessel, thereby allowing byproducts to leave the vessel selectively.

Carbon-bearing precursor species will vary depending on the desired characteristics, but can include hydrocarbons or hydrocarbon mixtures, including but not limited to, (a) alkane species: consisting of at least one of the straight or branched alkanes, for example: CH₄, C₂H₆, C₃H₈, C₄H₁₀, C₅H₁₂, C₆H₁₄, C₇H₁₆, C₈H₁₈, C₉H₂₀, C₁₀H₂₂, C₁₁H₂₄, C₁₂H₂₆, C₁₃H₂₈, C₁₄H₃₀, ₁₅H₃₂, C₁₆H₃₄, C₁₇H₃₆, C₁₈H₃₈, C₁₉H₄₀, C₂₀H₄₂, C₂₁H₄₄, C₂₂H₄₆, C₂₃H₄₈, C₂₄H₅₀, C₂₅H₅₂, C₂₆H₅₄, C₂₇H₅₆, C₂₈H₅₈, C₂₉H₆₀, C₃₀H₆₂, C₃₁H₆₄, C₃₂H₆₆, C₃₃H₆₈, C₃₄H₇₀, C₃₅H₇₂, C₃₆H₇₄, C₃₇H₇₆, C₃₈H₇₈, C₃₉H₈₀, C₄₀H₈₂, C₄₁H₈₄, C₄₂H₈₆, C₄₃H₈₈, C₄₄H₉₀, C₄₅H₉₂, C₄₆H₉₄, C₄₇H₉₆, C₄₈H₉₈, C₄₉H₁₀₀, C₅₀H₁₀₂, C₅₁H₁₀₄, C₅₂H₁₀₆, C₅₃H₁₀₈, C₅₄H₁₁₀, C₅₅H₁₁₂, C₅₆H₁₁₄, C₅₇H₁₁₆, C₅₈H₁₁₈, C₅₉H₁₂₀, C₆₀H₁₂₂, C₆₁H₁₂₄, C₆₂H₁₂₆, C₆₃H₁₂₈, C₆₄H₁₃₀, C₆₅H₁₃₂, C₆₆H₁₃₄, C₆₇H₁₃₆, C₆₈H₁₃₈, C₆₉H₁₄₀, C7oH₁₄₂, C₇₁H₁₄₄, C₇₂H₁₄₆, C₇₃H₁₄₈, C₇₄H₁₅₀, C₇₅H₁₅₂, C₇₆H₁₅₄, C₇₇H₁₅₆, C₇₈H₁₅₈, C₇₉H₁₆₀, C₈₀H₁₆₂, C₈₁H₁₆₄, C₈₂H₁₆₆, C₈₃H₁₆₈, C₈₄H₁₇₀, C₈₅H₁₇₂, C₈₆H₁₇₄, C₈₇H₁₇₆, C₈₈H₁₇₈, C₈₉H₁₈₀, C₉₀H₁₈₂, C₉₁H₁₈₄, C₉₂H₁₈₆, C₉₃H₁₈₈, C₉₄H₁₉₀, C₉₅H₁₉₂, C₉₆H₁₉₄, C₉₇H₁₉₆, C₉₈H₁₉₈, C₉₉H₂₀₀, C₁₀₀H₂₀₂, C₁₀₁H₂₀₄, C₁₀₂H₂₀₆, C₁₀₃H₂₀₈, C₁₀₄H₂₁₀, C₁₀₅H₂₁₂, C₁₀₆H₂₁₄, C₁₀₇H₂₁₆, C₁₀₈H₂₁₈, C₁₀₉H₂₂₀, C₁₁₀H₂₂₂, C₁₁₁H₂₂₄, C₁₁₂H₂₂₆, C₁₁₃H₂₂₈, C₁₁₄H₂₃₀, C₁₁₅H₂₃₂, C₁₁₆H₂₃₄, C₁₁₇H₂₃₆, C₁₁₈H₂₃₈, C₁₁₉H₂₄₀, C₁₂₀H₂₄₂; (b) alkene species, consisting of at least one of the straight or branched alkenes, for example: C₂H₄, C₃H₆, C₄H₈, C₅H₁₀, C₆H₁₂, C₇H₁₄, C₈H₁₆, C₉H₁₈, C₁₀H₂₀, C₁₁H₂₂, C₁₂H₂₄, C₁₃H₂₆, C₁₄H₂₈, C₁₅H₃₀, C₁₆H₃₂, C₁₇H₃₄, C₁₈H₃₆, C₁₉H₃₈, C₂₀H₄₀, C₂₁H₄₂, C₂₂H₄₄, C₂₃H₄₆, C₂₄H₄₈, C₂₅H₅₀, C₂₆H₅₂, C₂₇H₅₄, C₂₈H₅₆, C₂₉H₅₈, C₃₀H₆₀, C₃₁H₆₂, C₃₂H₆₄, C₃₃H₆₆, C₃₄H₆₈, C₃₅H₇₀, C₃₆H₇₂, C₃₇H₇₄, C₃₈H₇₆, C₃₉H₇₈, C₄₀H₈₀, C₄₁H₈₂, C₄₂H₈₄, C₄₃H₈₆, C₄₄H₈₈, C₄₅H₉₀, C₄₆H₉₂, C₄₇H₉₄, C₄₈H₉₆, C₄₉H₉₈, C₅₀H₁₀₀, C₅₁H₁₀₂, C₅₂H₁₀₄, C₅₃H₁₀₆, C₅₄H₁₀₈, C₅₅H₁₁₀, C₅₆H₁₁₂, C₅₇H₁₁₄, C₅₈H₁₁₆, C₅₉H₁₁₈, C₆₀H₁₂₀, C₆₁H₁₂₂, C₆₂H₁₂₄, C₆₃H₁₂₆, C₆₄H₁₂₈, C₆₅H₁₃₀, C₆₆H₁₃₂, C₆₇H₁₃₄, C₆₈H₁₃₆, C₆₉H₁₃₈, C7oH₁₄₀, C₇₁H₁₄₂, C₇₂H₁₄₄, C₇₃H₁₄₆, C₇₄H₁₄₈, C₇₅H₁₅₀, C₇₆H₁₅₂, C₇₇H₁₅₄, C₇₈H₁₅₆, C₇₉H₁₅₈, C₈₀H₁₆₀, C₈₁H₁₆₂, C₈₂H₁₆₄, C₈₃H₁₆₆, C₈₄H₁₆₈, C₈₅H₁₇₀, C₈₆H₁₇₂, C₈₇H₁₇₄, C₈₈H₁₇₆, C₈₉H₁₇₈, C₉₀H₁₈₀, C₉₁H₁₈₂, C₉₂H₁₈₄, C₉₃H₁₈₆, C₉₄H₁₈₈, C₉₅H₁₉₀, C₉₆H₁₉₂, C₉₇H₁₉₄, C₉₈H₁₉₆, C₉₉H₁₉₈, C₁₀₀H₂₀₀, C₁₀₁H₂₀₂, C₁₀₂H₂₀₄, C₁₀₃H₂₀₆, C₁₀₄H₂₀₈, C₁₀₅H₂₁₀, C₁₀₆H₂₁₂, C₁₀₇H₂₁₄, C₁₀₈H₂₁₆, C₁₀₉H₂₁₈, C₁₁₀H₂₂₀, C₁₁₁H₂₂₂, C₁₁₂H₂₂₄, C₁₁₃H₂₂₆, C₁₁₄H₂₂₈, C₁₁₅H₂₃₀, C₁₁₆H₂₃₂, C₁₁₇H₂₃₄, C₁₁₈H₂₃₆, C₁₁₉H₂₃₈, C₁₂₀H₂₄₀; (c) alkene species, consisting of at least one of the straight or branched alkynes, for example: C₂H₂, C₃H₄, C₄H₆, C₅H₈, C₆H₁₀, C₇H₁₂, C₈H₁₄, C₉H₁₆, C₁₀H₁₈, C₁₁H₂₀, C₁₂H₂₂, C₁₃H₂₄, C₁₄H₂₆, C₁₅H₂₈, C₁₆H₃₀, C₁₇H₃₂, C₁₈H₃₄, C₁₉H₃₆, C₂₀H₃₈, C₂₁H₄₀, C₂₂H₄₂, C₂₃H₄₄, C₂₄H₄₆, C₂₅H₄₈, C₂₆H₅₀, C₂₇H₅₂, C₂₈H₅₄, C₂₉H₅₆, C₃₀H₅₈, C₃₁H₆₀, C₃₂H₆₂, C₃₃H₆₄, C₃₄H₆₆, C₃₅H₆₈, C₃₆H₇₀, C₃₇H₇₂, C₃₈H₇₄, C₃₉H₇₆, C₄₀H₇₈, C₄₁H₈₀, C₄₂H₈₂, C₄₃H₈₄, C₄₄H₈₆, C₄₅H₈₈, C₄₆H₉₀, C₄₇H₉₂, C₄₈H₉₄, C₄₉H₉₆, C₅₀H₉₈, C₅₁H₁₀₀, C₅₂H₁₀₂, C₅₃H₁₀₄, C₅₄H₁₀₆, C₅₅H₁₀₈, C₅₆H₁₁₀, C₅₇H₁₁₂, C₅₈H₁₁₄, C₅₉H₁₁₆, C₆₀H₁₁₈, C₆₁H₁₂₀, C₆₂H₁₂₂, C₆₃H₁₂₄, C₆₄H₁₂₆, C₆₅H₁₂₈, C₆₆H₁₃₀, C₆₇H₁₃₂, C₆₈H₁₃₄, C₆₉H₁₃₆, C7oH₁₃₈, C₇₁H₁₄₀, C₇₂H₁₄₂, C₇₃H₁₄₄, C₇₄H₁₄₆, C₇₅H₁₄₈, C₇₆H₁₅₀, C₇₇H₁₅₂, C₇₈H₁₅₄, C₇₉H₁₅₆, C₈₀H₁₅₈, C₈₁H₁₆₀, C₈₂H₁₆₂, C₈₃H₁₆₄, C₈₄H₁₆₆, C₈₅H₁₆₈, C₈₆H₁₇₀, C₈₇H₁₇₂, C₈₈H₁₇₄, C₈₉H₁₇₆, C₉₀H₁₇₈, C₉₁H₁₈₀, C₉₂H₁₈₂, C₉₃H₁₈₄, C₉₄H₁₈₆, C₉₅H₁₈₈, C₉₆H₁₉₀, C₉₇H₁₉₂, C₉₈H₁₉₄, C₉₉H₁₉₆, C₁₀₀H₁₉₈, C₁₀₁H₂₀₀, C102H₂₀₂, C₁₀₃H₂₀₄, C₁₀₄H₂₀₆, C₁₀₅H₂₀₈, C₁₀₆H₂₁₀, C₁₀₇H₂₁₂, C₁₀₈H₂₁₄, C₁₀₉H₂₁₆, C₁₁₀H₂₁₈, C₁₁₁H₂₂₀, C₁₁₂H₂₂₂, C₁₁₃H₂₂₄, C₁₁₄H₂₂₆, C₁₁₅H₂₂₈C₁₁₆H₂₃₀, C₁₁₇H₂₃₂, C₁₁₈H₂₃₄, C₁₁₉H₂₃₆, C₁₂₀H₂₃₈; (d) cycloalkanes, for example: C₃H₆, C₄H₈, C₅H₁₀, C₆H₁₂, C₇H₁₄, C₈H₁₆, C₉H₁₈, C₁₀H₂₀, C₁₁H₂₂, C₁₂H₂₄, C₁₃H₂₆, C₁₄H₂₈, C₁₅H₃₀, C₁₆H₃₂, C₁₇H₃₄, C₁₈H₃₆, C₁₉H₃₈, C₂₀H₄₀, C₂₁H₄₂, C₂₂H₄₄, C₂₃H₄₆, C₂₄H₄₈, C₂₅H₅₀, C₂₆H₅₂, C₂₇H₅₄, C₂₈H₅₆, C₂₉H₅₈, C₃₀H₆₀, C₃₁H₆₂, C₃₂H₆₄, C₃₃H₆₆, C₃₄H₆₈, C₃₅H₇₀, C₃₆H₇₂, C₃₇H₇₄, C₃₈H₇₆, C₃₉H₇₈, C₄₀H₈₀, C₄₁H₈₂, C₄₂H₈₄, C₄₃H₈₆, C₄₄H₈₈, C₄₅H₉₀, C₄₆H₉₂, C₄₇H₉₄, C₄₈H₉₆, C₄₉H₉₈, C₅₀H₁₀₀, C₅₁H₁₀₂, C₅₂H₁₀₄, C₅₃H₁₀₆, C₅₄H₁₀₈, C₅₅H₁₁₀, C₅₆H₁₁₂, C₅₇H₁₁₄, C₅₈H₁₁₆, C₅₉H₁₁₈, C₆₀H₁₂₀, C₆₁H₁₂₂, C₆₂H₁₂₄, C₆₃H₁₂₆, C₆₄H₁₂₈, C₆₅H₁₃₀, C₆₆H₁₃₂, C₆₇H₁₃₄, C₆₈H₁₃₆, C₆₉H₁₃₈, C₇₀H₁₄₀, C₇₁H₁₄₂, C₇₂H₁₄₄, C₇₃H₁₄₆, C₇₄H₁₄₈, C₇₅H₁₅₀, C₇₆H₁₅₂, C₇₇H₁₅₄, C₇₈H₁₅₆, C₇₉H₁₅₈, C₈₀H₁₆₀, C₈₁H₁₆₂, C₈₂H₁₆₄, C₈₃H₁₆₆, C₈₄H₁₆₈, C₈₅H₁₇₀, C₈₆H₁₇₂, C₈₇H₁₇₄, C₈₈H₁₇₆, C₈₉H₁₇₈, C₉₀H₁₈₀, C₉₁H₁₈₂, C₉₂H₁₈₄, C₉₃H₁₈₆, C₉₄H₁₈₈, C₉₅H₁₉₀, C₉₆H₁₉₂, C₉₇H₁₉₄, C₉₈H₁₉₆, C₉₉H₁₉₈, C₁₀₀H₂₀₀, C₁₀₁H₂₀₂, C₁₀₂H₂₀₄, C₁₀₃H₂₀₆, C₁₀₄H₂₀₈, C₁₀₅H₂₁₀, C₁₀₆H₂₁₂, C₁₀₇H₂₁₄, C₁₀₈H₂₁₆, C₁₀₉H₂₁₈, C₁₁₀H₂₂₀, C₁₁₁H₂₂₂, C₁₁₂H₂₂₄, C₁₁₃H₂₂₆, C₁₁₄H₂₂₈, C₁₁₅H₂₃₀, C₁₁₆H₂₃₂, C₁₁₇H₂₃₄, C₁₁₈H₂₃₆, C₁₁₉H₂₃₈, C₁₂₀H₂₄₀, C₆H₁₀, C₇H₁₂, C₈H₁₄, C₉H₁₆, C₁₀H₁₈, C₁₁H₂₀, C₁₂H₂₂, C₁₃H₂₄, C₁₄H₂₆, C₁₅H₂₈, C₁₆H₃₀, C₁₇H₃₂, C₁₈H₃₄, C₁₉H₃₆, C₂₀H₃₈, C₂₁H₄₀, C₂₂H₄₂, C₂₃H₄₄, C₂₄H₄₆, C₂₅H₄₈, C₂₆H₅₀, C₂₇H₅₂, C₂₈H₅₄, C₂₉H₅₆, C₃₀H₅₈, C₃₁H₆₀, C₃₂H₆₂, C₃₃H₆₄, C₃₄H₆₆, C₃₅H₆₈, C₃₆H₇₀, C₃₇H₇₂, C₃₈H₇₄, C₃₉H₇₆, C₄₀H₇₈, C₄₁H₈₀, C₄₂H₈₂, C₄₃H₈₄, C₄₄H₈₆, C₄₅H₈₈, C₄₆H₉₀, C₄₇H₉₂, C₄₈H₉₄, C₄₉H₉₆, C₅₀H₉₈, C₅₁H₁₀₀, C₅₂H₁₀₂, C₅₃H₁₀₄, C₅₄H₁₀₆, C₅₅H₁₀₈, C₅₆H₁₁₀, C₅₇H₁₁₂, C₅₈H₁₁₄, C₅₉H₁₁₆, C₆₀H₁₁₈, C₆₁H₁₂₀, C₆₂H₁₂₂, C₆₃H₁₂₄, C₆₄H₁₂₆, C₆₅H₁₂₈, C₆₆H₁₃₀, C₆₇H₁₃₂, C₆₈H₁₃₄, C₆₉H₁₃₆, C7oH₁₃₈, C₇₁H₁₄₀, C₇₂H₁₄₂, C₇₃H₁₄₄, C₇₄H₁₄₆, C₇₅H₁₄₈, C₇₆H₁₅₀, C₇₇H₁₅₂, C₇₈H₁₅₄, C₇₉H₁₅₆, C₈₀H₁₅₈, C₈₁H₁₆₀, C₈₂H₁₆₂, C₈₃H₁₆₄, C₈₄H₁₆₆, C₈₅H₁₆₈, C₈₆H₁₇₀, C₈₇H₁₇₂, C₈₈H₁₇₄, C₈₉H₁₇₆, C₉₀H₁₇₈, C₉₁H₁₈₀, C₉₂H₁₈₂, C₉₃H₁₈₄, C₉₄H₁₈₆, C₉₅H₁₈₈, C₉₆H₁₉₀, C₉₇H₁₉₂, C₉₈H₁₉₄, C₉₉H₁₉₆, C₁₀₀H₁₉₈, C₁₀₁H₂₀₀, C₁₀₂H₂₀₂, C₁₀₃H₂₀₄, C₁₀₄H₂₀₆, C₁₀₅H₂₀₈, C₁₀₆H₂₁₀, C₁₀₇H₂₁₂, C₁₀₈H₂₁₄, C₁₀₉H₂₁₆, C₁₁₀H₂₁₈, C₁₁₁H₂₂₀, C₁₁₂H₂₂₂, C₁₁₃H₂₂₄, C₁₁₄H₂₂₆, C₁₁₅H₂₂₈, C₁₁₆H₂₃₀, C₁₁₇H₂₃₂, C₁₁₈H₂₃₄, C₁₁₉H₂₃₆, C₁₂₀H₂₃₈; (e) cyclic/aromatic hydrocarbons or polycyclic aromatic hydrocarbons, for example, benzene (C₆H₆), toluene (C₇H₈), xylene (C₈H₁₀), indane (C₉H₁₀), naphthalene (C₁₀H₈), tetralin (C₁₀H₁₆), methylnaphthalene (C₁₁H₁₀), azulene (C₁₀H₈), anthracene (C₁₄H₁₀), pyrene (C₁₆H₁₀); and (f) diamondoid/adamantane-bearing species, such as: adamantane (C₁₀H₁₆), Iceane (C₁₂H₁₈), BC-8 (C₁₄H₁₈), diamantane (C₁₄H₂₀), triamantane (C₁₈H₂₄), tetramantane (C₂₂H₂₈), pentamantane (C₂₆H₃₂), cyclohexamantane (C₂₆H₃₀), C₃₀H₃₄, C₃₀H₃₆, C₃₄H₄₀, C₃₈H₄₄, C₄₂H₄₈, C₄₆H₅₂, C₅₀H₅₆, C₅₄H₆₀, C₅₈H₆₄, C₆₂H₆₈, C₆₆H₇₂, C₇₀H₇₆, C₇₄H₈₀, C₇₈H₈₄, C₈₂H₈₈, C₈₆H₉₂, C₉₀H₉₆, C₉₄H₁₀₀,C₉₈H₁₀₄, C₁₀₂H₁₀₈, C₁₀₆H₁₁₂, C₁₁₀H₁₁₆, C₁₁₄H₁₂₀, C₁₁₈H₁₂₄, C₁₂₂H₁₂₈.

The CB precursor species can also be or include (a) waxes, e.g. paraffin wax or carnauba wax; (b) natural gas; (c) kerosene; (d) gasoline; or (e) natural or synthetic oils.

In other embodiments, the CB precursor species can be (a) a fluorinated hydrocarbon, e.g. a fluoroalkane, fluoroalkene, fluoroalkyne, or cyclic fluorocarbon (b) chlorinated hydrocarbons, e.g. tetrchloromethane, tetracloroethylene, tetrachlorobenzene, hexachlorobenzene, perchlorohexane, perchloroheptane, perchlorooctane, etc.; (c) bromiated hydrocarbons, e.g. tetrabromomethane, tetrabromoethylene, tetrabromobenzene, hexabromobenzene, perbromohexane, etc.; (d) iodated hydrocarbons, e.g. tetraiodomethane, tetraiodoethylene, tetraiodobenzene, hexaiodobenzene, etc.; and/or (e) organo-xenon compound, e.g. (C6F5)2Xe, or C5f5XeF.

The dopant bearing (DB) precursor species can include, as examples: (a) a metal hydride, metallorganic, metal halide, or metallocene precursor, wherein said metal is at least one of the following elements: Li, B, Mg, Al, Ti, V, Cr, Mn, Fe, Co, Ni, Cu, Zn, Ga, Ge, Y, Zr, Nb, Mo, Tu, Rh, Pd, Ag, Cd, In, Sn, I, La, Ce, Pr, Nd, Sm, Eu, Gd, Ho, Er, Yb, Hf, Ta, W, Re, Os, Ir, Pt, Au, Bi, Th, U, Np, Pu, Am, Cm, and Cf; (b) where the (DB) precursor species contain(s) at least one the following elements: B, N, O, Si, S, F, Br, Cl, and I; as well as at least one of the following elements: Li, B, Mg, Al, Si, Ti, V, Cr, Mn, Fe, Co, Ni, Cu, Zn, Ga, Ge, Y, Zr, Nb, Mo, Tu, Rh, Pd, Ag, Cd, In, Sn, I, La, Ce, Pr, Nd, Sm, Eu, Gd, Ho, Er, Yb, Hf, Ta, W, Re, Os, Ir, Pt, Au, Bi, Th, U, Np, Pu, Am, Cm, and Cf.

In some embodiments, the LMM precursor species includes at least one carbon-bearing species, including but not limited, at least one of: methane, ethane, propane, butane, pentane, hexane, ethene, propene, butene, pentene, ethyne, propyne, butyne, pentyne, cyclopropane, cyclobutane, cyclopentane, cyclopropene, cyclobutene, and cyclopentene.

In some embodiments, the HMM precursor species includes at least one carbon-bearing species, including but not limited to, at least one of: (1) the alkanes, CₙH₂ₙ₊₂ where n=>6, (2) the alkenes, CₙH₂ₙ₊₂ where n=>6, (3) the alkynes, CₙH₂ₙ₊₂ where n>=6, (4) cyclic/aromatic hydrocarbons, e.g. cyclohexane, cyclohexene, benzene, benzyne, toluene, naphthalene, and (5) large diamondoids, e.g. adamantane, etc.

In some embodiments, the HMM precursor species includes at least one carbon-bearing species, including but not limited to (a) at least one halocarbon species; (b) a halogenated hydrocarbon or carbon halide species, including at least one haloalkane species (e.g. tetrafluoromethane, tetrachloromethane, tetrabromomethane, tetraiodomethane, trifluoromethane, trichloromethane, tribromomethane, triiodomethane, difluoromethane, dichloromethane, dibromomethane, diiodomethane, fluoromethane, chloromethane, bromomethane, iodomethane, tetrafluoroethane, etc.); (c) a haloalkene species (e.g. tetrafluoroethene, tetrachloroethene, tetrabromoethene, tetraiodoethene, trifluoroethene, trichloroethene, tribromoethene, triiodoethene, difluoroethene, dichloroethene, dibromoethene, diiodoethene, fluoroethene, chloroethene, bromoethene, iodoethene, tetrafluoroethene, etc.); (d) a haloalkyne species (e.g. tetrafluoroethyne, tetrachloroethyne, tetrabromoethyne, tetraiodoethyne, trifluoroethyne, trichloroethyne, tribromoethyne, triiodoethyne, difluoroethyne, dichloroethyne, dibromoethyne, diiodoethyne, fluoroethyne, chloroethyne, bromoethyne, iodoethyne, etc.); and/or (e) a halogenated aromatic compounds, e.g. hexafluorobenzene, hexachlorobenzene, hexabromobenzene, hexaiodobenzene, tetraiodobenzene, hexaiodobenzene, etc.

In some embodiments, the precursor species can include inert or reactive species, as examples, (a) argon, krypton, xenon, (b) hydrogen, nitrogen, fluorine, chlorine, bromine, iodine, (c) sulfur halides, e.g. sulfur hexafluoride, trisulfur dichloride, or disulfur diiodide. This is certainly not intended as an exhaustive list.

In some embodiments, the dopant precursor species can include silicon precursors: (a) silanes, e.g. silane, disilane, trisilane, tetrasilane; (b) silicon halides, e.g. silicon fluoride, silicon chloride, silicon bromide, or silicon iodide, (c) halosilanes, e.g. fluorosilane, chlorosilane, bromosilane, or iodosilane, or (d) organosilicon species, e.g. diethylsilane, ethyltrichlorosilane, diethyldichlorosilane, hexamethyldisilane, tetramethylsilane, trimethylsilane, methyltrichlorosilane, dimethyldichlorosilane, trimethylchlorosilane, trichlorosilane, dichlorodisilane, and dichlorotetradisilane. This is certainly not intended as an exhaustive list.

In some embodiments, the dopant precursor species can include boron precursors: (a) boanes, e.g. diborane, tetraborane, hexaborane; (b) boron halides, e.g. boron fluoride, boron chloride, boron bromide, or boron iodide, (c) haloboranes, e.g. fluoroborane, chloroborane, bromoborane, or iodoborane, or (d) organoboron species, e.g. trimethylborane, diethylborane, dim ethylchloroborane, methyldichloroborane, dimethylbromoborane, methyldibromoborane. This is certainly not intended as an exhaustive list.

### Ultra-High Temperature Fibrous Materials in the B—C—N—X System

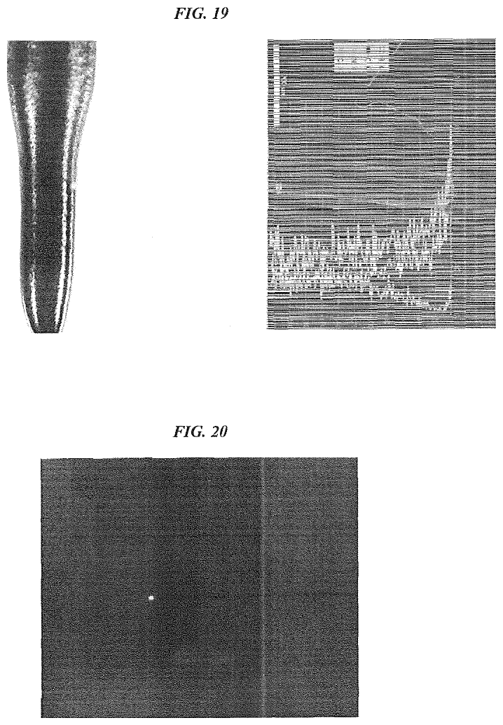

Applicant has grown a wide variety of fibrous materials within the B—C—N—X system, where B=boron, C=carbon, N=nitrogen, X is a dopant/alloy element, also referred to herein as an “additive element”; one example of an undoped fine-grained boron carbon nitride (BCN) fiber or fibrous material is shown in FIG. 19. This and similar fibrous materials have exhibited individual fiber tensile strengths exceeding 1 GPa.

Some HMM precursors for growing materials in the boron-carbon-nitride system include the use of such boron precursors as: hexaborane, B6H₁₀, borazine, B₃H₆N₃, trimethylborazine; BCHN, and such carbon precursors as: the alkanes, CₙH₂ₙ₊₂ where n=5-100, the alkenes, CₙH₂ₙ₊₂ where n=5-100, the alkynes, CₙH₂ₙ₊₂ where n=5-100, or cyclic hydrocarbons, e.g. cyclopentane; and such nitrogen sources as: triazole, C₂H₃N₃, azetidine, C₃H₇N, imidazole, C₃H₄N₂, imidazoline, C₃H₈N₂, pyrazoline, C₃H₆N₂, Triazine, C₃H₃N₃, azoethane, C₄H₁₀N₂, purine, C₅H₅N₄, ammonium chloride, NH₄Cl, ammonium bromide, NH₄Br, ammonium iodide, NH₄I, etc. Similarly, some LMM precursors for growing materials in the boron-carbon-nitride system include the use of boron sources, e.g.: diborane, B₂H₆, tetraborane, B₄H₁₀, and trimethylboron C₃H₉B, and the use of carbon sources, e.g: the alkanes, CₙH₂ₙ₊₂ where n=1-4, the alkenes, CₙH₂ₙ₊₂ where n=1-4, the alkynes, CₙH₂ₙ₊₂ where n=1-4, or cyclic hydrocarbons, e.g. cyclobutane; and the use of nitrogen sources, e.g: molecular nitrogen, ammonia, NH₃, hydrazine, N₂H₄, methylhydrazine, CH₆N₂, N₂H₄, azomethane, C₂H₆N₂, azete, C₃H₃N. Again these lists are not intended to be exhaustive. Note also that some of these precursors can supply more than one element at a time; for example trimethylborazine, can provide boron, carbon and nitrogen simultaneously.

In one preferred implementation of this invention, we have used trimethylborazine as an HMM precursor, and molecular nitrogen as an LMM precursor to grow BₓC_{y}N_{z} fibers or fibrous materials with approximately 1:1:1 stochiometry.

### Ultra-High Temperature Fibrous Materials in the Si—C—N—X System

Applicant has grown a wide variety of fibrous materials within the Si—C—N system, where Si=silicon, C=carbon, N=nitrogen, and X is a dopant/alloy element, also referred to herein as an “additive element”; one example of an undoped fine-grained silicon carbide fiber is shown in FIG. 20. This and similar fibrous materials have exhibited individual fiber tensile strengths of up to 4.3 GPa.

Some HMM precursors for growing materials in the silicon-carbon-nitride system include the use of such silicon precursors as: diethylsilane, ethyltrichlorosilane, diethyldichlorosilane, hexamethyldisilane, tetramethylsilane, trimethylsilane, methyltrichlorosilane, dimethyldichlorosilane, trimethylchlorosilane, trichlorosilane, dichlorodisilane, dichlorotetradisilane, silicon tetrachloride, silicon tetrabromide, or silicon tetraiodide; and such carbon precursors as: the alkanes, CₙH₂ₙ₊₂ where n=5-100, the alkenes, CₙH₂ₙ₊₂ where n=5-100, the alkynes, CₙH₂ₙ₊₂ where n=5-100, or cyclic hydrocarbons, e.g. cyclopentane; and such nitrogen sources as: triazole, C₂H₃N₃, azetidine, C₃H7N, imidazole, C₃H₄N₂, imidazoline, C₃H₈N₂, pyrazoline, C₃H₆N₂, Triazine, C₃H₃N₃, azoethane, C₄H₁₀N₂, purine, C₅H₅N₄, ammonium chloride, NH₄Cl, ammonium bromide, NH₄Br, ammonium iodide, NH₄I, etc. Similarly, some LMM precursors for growing materials in the silicon-carbon-nitride system include the use of silicon sources, e.g.: silane and disilane; and the use of carbon sources, e.g.: the alkanes, CₙH₂ₙ₊₂ where n=1-4, the alkenes, CₙH₂ₙ₊₂ where n=1-4, the alkynes, CₙH₂ₙ₊₂ where n=1-4, or cyclic hydrocarbons, e.g. cyclobutane; and the use of nitrogen sources, e.g.: molecular nitrogen, ammonia, NH_{3,} hydrazine, N₂H₄, methylhydrazine, CH₆N_{2,} N₂H₄, azomethane, C₂H₆N_{2,} azete, C₃H₃N. Again these lists are not intended to be exhaustive. Note also that some of these precursors can supply more than one element at a time; for example tetramethylsilane, can provide carbon as well as silicon, and triazole can provide carbon and nitrogen simultaneously.

In one preferred implementation of this invention, we have used tetramethylsilane as the HMM precursor and hydrogen as an LMM precursor to grow SiC and SiCₓ fibers or fibrous materials (where x is approximately 2) with tensile strengths exceeding 2 GPa.

### Ultra-High Temperature Fibrous Materials in the Ta—Hf—C—N—X System

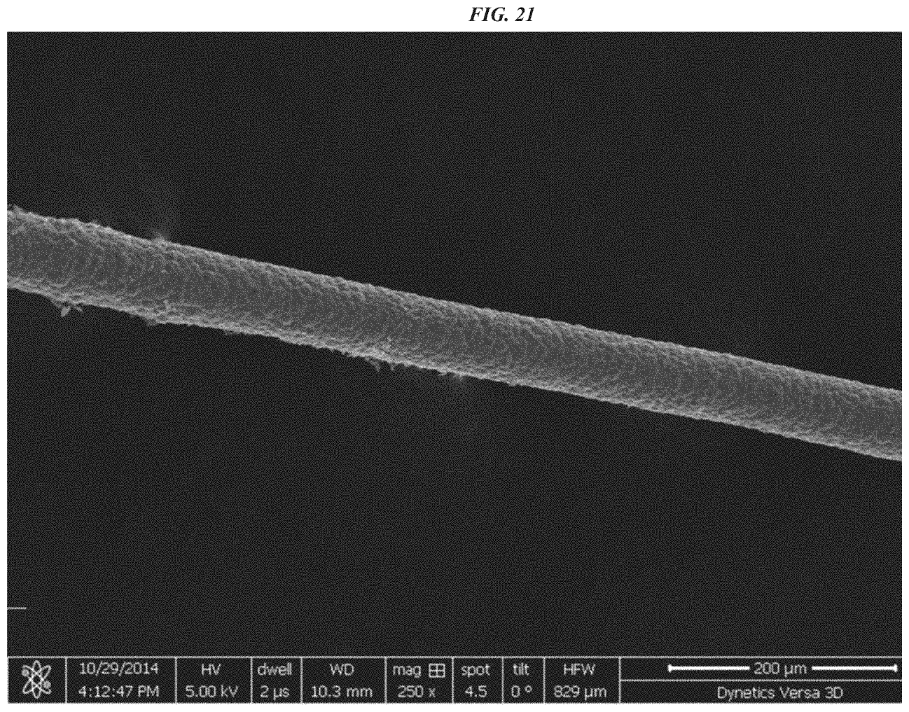

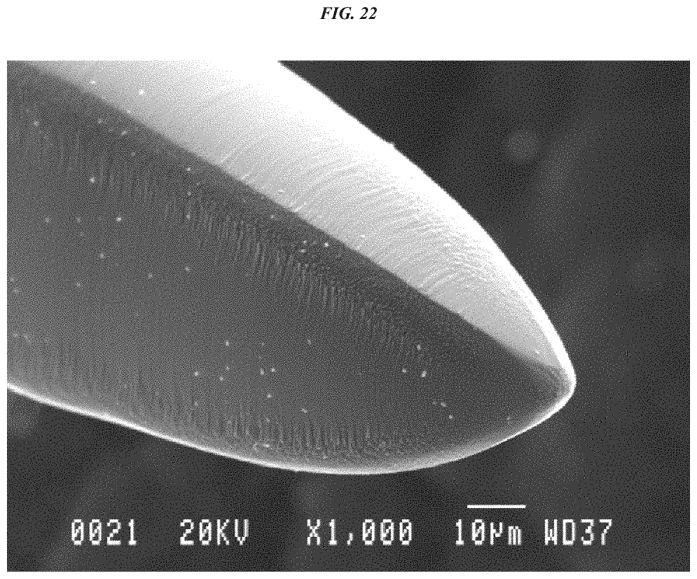

Applicant has grown a variety of fibrous materials within the Ta—Hf—C—N—X system, where Ta=tantalum, Hf=hafnium, C=carbon, N=nitrogen, and X is a dopant/alloy element, also referred to as an “additive element”; one example of an undoped fine-grained tantalum-hafnium-carbide (Ta—Hf—C) fiber is shown in FIG. 21. Fully dense TaC, HfC, and TaxHfyCz fibers with compositions centered around Ta₄HfC₅ (See FIG. 21 as an example) are also demonstrated. These are the most extreme refractory materials known. These materials can be grown continuously as fine-grained fibrous materials with uniform solid solutions of these elements. The fibrous materials exhibit enhanced strength, toughness, and high-temperature stability over compacted Ta—Hf—C based materials. Applicants have also demonstrated that a wide variety of other refractory metals and compounds can be deposited in a similar manner, e.g. the tungsten fiber shown in FIG. 22.

The addition of dopant/alloying elements, e.g. boron, silicon, titanium, and zirconium also allows grain-refinement of the Ta—Hf—C—N materials and help stabilize the resulting fine-grained deposit, inhibiting grain growth at high temperatures. Those metals (represented by “M”) in TaᵤHfᵥC_{w}N_{y}M_{z} that may be useful additives include: lithium, beryllium, boron, nitrogen, oxygen, fluorine, magnesium, aluminum, silicon, phosphorous, sulphur, chlorine, scandium, titanium, vanadium, chromium, manganese, iron, cobalt, nickel, copper, zinc, gallium, germanium, selenium, bromine, yttrium, zirconium, niobium, molybdenum, technetium, ruthenium, rhodium, palladium, silver, cadmium, indium, tin, antimony, tellurium, iodine, lanthanum, cerium, praseodymium, neodymium, promethium, samarium, gadolinium, terbium, dysprosium, holmium, erbium, thullium, Ytterbium, hafnium, tantalum, tungsten, rhenium, osmium, iridium, platinum, gold, mercury, lead, bismuth, actinium, thorium, uranium, neptunium, plutonium, americium, curium, and californium. Utilizing the system and methods herein, TaᵤHfᵥC_{w}, TaᵤHfᵥN_{y}, TaᵤHfᵥC_{w}N_{y}, TaᵤHfᵥC_{w}N_{y}B_{z}, and TaᵤHfᵥC_{w}N_{y}Si_{z}, and TaᵤHfᵥC_{w}N_{y}M_{z} fibers and fibrous materials can be produced, where the fibers and fibrous materials can be handled and used within metal- and ceramic- matrix composites. Even more complex compounds and alloys are also be possible to realize, e.g. TaᵤHfᵥC_{w}BₓN_{y}M_{z}.

In one embodiment, the fabricated fibrous material is comprised of only tantalum, hafnium, and carbon, wherein the concentration of tantalum is between 0-67 at. %, the concentration of hafnium is between 0-67 at. %, and the concentration of carbon is between 5-67 atomic percent (at. %), and where the concentration of tantalum, hafnium, and carbon are constrained to nominally total 100 at. %. For example, Ta₄HfC₅, would fall within this embodiment criteria, as well as the binary compounds TaC, TaC_{0.4}, HfC and HfC_{0.5}. Note that the fibrous material is still considered to be 100 at. % even if minor traces of additional elements are found within the fibrous material, where trace amounts are generally much less than 1 at. %.

In another embodiment, the fabricated fibrous material is a quaternary alloy. In this embodiment, the fibrous material is comprised of tantalum, hafnium, and carbon, and nitrogen, wherein the concentration of tantalum is between 0-67 at. %, the concentration of hafnium is between 0-67 at. %, the concentration of carbon is between 0-67 atomic percent (at. %), and the concentration of nitrogen is between 0-67%, where the concentration of tantalum, hafnium, carbon, and nitrogen are constrained to nominally total 100 at. %. For example, binary compounds HfN, TaN, and ternary Hf—C—N compounds fall within this definition.

In another embodiment, the fabricated fibrous material is a quinary alloy, of the form TaᵤHfᵥC_{w}N_{y}M_{z,}, and is composed of is comprised of tantalum, hafnium, and carbon, and nitrogen, and a dopant/alloy element M (as an “additive element”). The concentration of said dopant/alloy element is between 0-35 at. %, where the concentration of tantalum, hafnium, carbon, nitrogen, and additive element are constrained to nominally total 100 at. %. The dopant/alloy element, M, can be a variety of elements, including: lithium, beryllium, boron, nitrogen, oxygen, fluorine, magnesium, aluminum, silicon, phosphorous, sulphur, chlorine, scandium, titanium, vanadium, chromium, manganese, iron, cobalt, nickel, copper, zinc, gallium, germanium, selenium, bromine, yttrium, zirconium, niobium, molybdenum, technetium, ruthenium, rhodium, palladium, silver, cadmium, indium, tin, antimony, tellurium, iodine, lanthanum, cerium, praseodymium, neodymium, promethium, samarium, gadolinium, terbium, dysprosium, holmium, erbium, thullium, Ytterbium, hafnium, tantalum, tungsten, rhenium, osmium, iridium, platinum, gold, mercury, lead, bismuth, actinium, thorium, uranium, neptunium, plutonium, americium, curium, and californium.

In another embodiment, the fabricated fibrous material is a 6-part alloy, of the form TaᵤHFᵥC_{w}BₓN_{y}M_{z}, and is comprised of tantalum, hafnium, carbon, boron, and nitrogen, and a dopant/alloy element M (as an “additive element”). The concentration of said dopant/alloy element is between 0-35 at. %, where the concentration of tantalum, hafnium, carbon, boron, nitrogen, and additive element are constrained to nominally total 100 at. %. The dopant/alloy element, M, can be a variety of elements, including: lithium, beryllium, boron, nitrogen, oxygen, fluorine, magnesium, aluminum, silicon, phosphorous, sulphur, chlorine, scandium, titanium, vanadium, chromium, manganese, iron, cobalt, nickel, copper, zinc, gallium, germanium, selenium, bromine, yttrium, zirconium, niobium, molybdenum, technetium, ruthenium, rhodium, palladium, silver, cadmium, indium, tin, antimony, tellurium, iodine, lanthanum, cerium, praseodymium, neodymium, promethium, samarium, gadolinium, terbium, dysprosium, holmium, erbium, thullium, Ytterbium, hafnium, tantalum, tungsten, rhenium, osmium, iridium, platinum, gold, mercury, lead, bismuth, actinium, thorium, uranium, neptunium, plutonium, americium, curium, and californium.

In any of the embodiments, the “fibrous material” can be an array of fibers, a TOW of fibers, a braided rope, a weaved fabric, or a randomized wool of fibers, as described earlier. Each fiber in such a fibrous material can be substantially a homogeneous single-phase material, with various fine crystal structures, e.g. amorphous/glassy-, ultrafine grained-, fine-grained-, and polycrystalline fibers, or single-crystal structures, as defined previously. The fibers can be fabricated using the methods and techniques herein, wherein the atomic percentages vary by no more than 2.5% along the length of any one fiber.

Examples of precursors that can be used to fabricate the TaᵤHfᵥC_{w}BₓN_{y}M_{z}, and simpler fibrous materials, include: (1) for tantalum: tantalum fluoride, tantalum chloride, tantalum bromide, tantalum iodide; (2) for hafnium: hafnium fluoride, hafnium chloride, hafnium bromide, hafnium iodide; (3) for carbon: all of the precursors described in the doped carbon section above; (4) for boron: (a) diborane, tetraborane, hexaborane; (b) boron halides, e.g. boron fluoride, boron chloride, boron bromide, or boron iodide, (c) haloboranes, e.g. fluoroborane, chloroborane, bromoborane, or iodoborane, or (d) organoboron species, e.g. trimethylborane, diethylborane, dim ethylchloroborane, methyldichloroborane, dimethylbromoborane, methyldibromoborane; and (5) for nitrogen: molecular nitrogen, ammonia, hydronitrogen compounds, and nitrogen substituted hydrocarbons and aromatic compounds. This is not intended as an exhaustive list.

There are many possible UHTM applications of this technology, including aerospace ablators and rockets, extreme temperature molds, novel insulation and fire blocking, fire-proof paper, archival recording of information (see U.S. patent application Ser. No. 62/074,739), nuclear reactor cladding, chemical reactor walls, furnace shielding, welding blankets, rocket engine components, etc. For example, the Ta—Hf—C fiber-based composites are expected to have a great impact on future nuclear thermal propulsion (“NTP”) rocket engine development, resulting in ISPs of over 1200 seconds.

What is claimed is:

1. A fibrous material comprising at least a first element and a second element,
a. wherein said first and second elements are at least two of tantalum, hafnium, carbon, boron, nitrogen and an additive element, and
b. wherein the concentration of nitrogen, if present, is no greater than 67 atomic percent, and the concentration of the additive element, if present, is no greater than 67 atomic percent, and
c. wherein said fibrous material is grown in at least one localized reaction zone from gaseous, liquid, semi-solid, critical, or supercritical precursor fluid mixtures using at least one primary heating means.

2. The fibrous material of claim 1, wherein said first element is tantalum and said second element is hafnium, and further comprising carbon and at least one additive element, wherein the concentration of tantalum is no greater than 95 atomic percent, the concentration of hafnium is no greater than 95 atomic percent, and the concentration of carbon is between 5-67 atomic percent, and the concentration of the at least one additive element is no greater than 35 atomic percent.

3. The fibrous material of claim 1, wherein said first element is tantalum and said second element is hafnium, and further comprising carbon, wherein the concentration of tantalum is no greater than 95 atomic percent, the concentration of hafnium is no greater than 95 atomic percent, and the concentration of carbon is between 5-67 atomic percent.

4. The fibrous material of claim 1, wherein the first element is tantalum and said second element is hafnium, and further comprising carbon, wherein the concentration of tantalum is between 35-45 atomic percent, the concentration of hafnium is between 5-15 atomic percent, and the concentration of carbon is between 45-55 atomic percent.

5. The fibrous material of claim 1, wherein said fibrous material is comprised of one or more fibers, wherein said fibers each have a length to diameter aspect ratio of at least 3:1.

6. The fibrous material of claim 1, wherein said fibrous material is at least one of single fiber strand, many fiber strands, short-shaped fibers, an array of fibers, tows, ropes, fabrics, textiles, wools, lattices, nano/microstructures, mesostructured materials, and sponge-like materials.

7. The fibrous material of claim 1, wherein said additive element is at least one of lithium, beryllium, boron, nitrogen, oxygen, fluorine, magnesium, aluminum, silicon, phosphorous, sulphur, chlorine, scandium, titanium, vanadium, chromium, manganese, iron, cobalt, nickel, copper, zinc, gallium, germanium, selenium, bromine, yttrium, zirconium, niobium, molybdenum, technetium, ruthenium, rhodium, palladium, silver, cadmium, indium, tin, antimony, tellurium, iodine, lanthanum, cerium, praseodymium, neodymium, promethium, samarium, gadolinium, terbium, dysprosium, holmium, erbium, thullium, Ytterbium, hafnium, tantalum, tungsten, rhenium, osmium, iridium, platinum, gold, mercury, lead, bismuth, actinium, thorium, uranium, neptunium, plutonium, americium, curium, and californium.

8. The fibrous material of claim 1, wherein said fibrous material has an internal crystalline structure that is one of
a. amorphous, glassy, vitreous, random non-crystalline, or quasi-crystalline morphologies, wherein no apparent long-range order exists at length scales of 35 nm or above;
b. nanocrystalline morphologies, with grain sizes smaller than 100 nm;
c. crystalline ultra fine-grained morphologies, with grain sizes between 100-500 nm;
d. crystalline, fine-grained morphologies with grain sizes smaller than 5 microns; and
e. single crystals.

9. The fibrous material of claim 1, wherein at least one thermal diffusion region is present at or near said localized reaction zones, wherein said thermal diffusion region is at least partially controlled by a secondary heating means.

10. The fibrous material of claim 9, wherein said precursor fluid mixtures comprise a mixture of low molar mass and high molar mass precursors.
